(19) United States
(12) Patent Application Publication
(10) Pub. No.: US 2026/0190569 A1
(43) Pub. Date: Jul. 2, 2026

(54) DISPLAY PANEL AND ELECTRONIC DEVICES INCLUDING THE SAME

(71) Applicant: Samsung Display Co., Ltd., Yongin-si (KR)

(72) Inventors: Junhyeong Park, Yongin-si (KR); Junsu Park, Yongin-si (KR); Younjoo Lee, Yongin-si (KR)

(21) Appl. No.: 19/409,911

(22) Filed: Dec. 5, 2025

(30) Foreign Application Priority Data
Dec. 27, 2024 (KR) 10-2024-0199333

(51) Int. Cl. H10H 29/41; H10D 86/40; H10D 86/60; H10H 29/32; H10H 29/49; H10H 29/85

(52) U.S. Cl. CPC H10H 29/41; H10H 29/32; H10H 29/49; H10H 29/8508; H10D 86/441; H10D 86/60

(57) ABSTRACT

A display panel including a base layer including a display area and a non-display area around the display area, a first pixel circuit layer in the display area of the base layer and including a transistor and insulating layers, at least one first light-emitting diode on the first pixel circuit layer and electrically connected to the transistor of the first pixel circuit layer, and a first protecting layer on the first pixel circuit layer and covering the at least one first light-emitting diode, wherein the first protecting layer includes a first pattern from which a portion of the first protecting layer is removed, and the first pattern is spaced from the at least one first light-emitting diode in a plan view.

### CROSS-REFERENCE TO RELATED APPLICATION

The present application claims priority to and the benefit of Korea Patent Application No. 10-2024-0199333, filed on Dec. 27, 2024, in the Korean Intellectual Property Office, the entire disclosure of which is incorporated by reference herein.

### 1. FIELD

The present disclosure relates to a display panel and an electronic device including the same.

### 2. DESCRIPTION OF THE RELATED ART

With the development of display panels that visually display electrical signals in general, various display panels having excellent characteristics such as small thickness, light weight, and low power consumption, and electronic devices including the display panels have been introduced. For example, research and development are being actively conducted on display panels having various structures, such as flexible display panels capable of being folded and/or rolled into a roll shape and stretchable display panels, and electronic devices including the same.

### SUMMARY

Embodiments of the present disclosure are to provide a display panel having an improved elongation property and realizing an excellent-quality image even when elongated, and an electronic device including the same. However, such problems are only examples, and the scope of the present disclosure is not limited thereby.

One or more embodiments of the present disclosure provides a display panel including a base layer including a display area and a non-display area around the display area, a first pixel circuit layer in the display area of the base layer and including a transistor and insulating layers, at least one first light-emitting diode on the first pixel circuit layer and electrically connected to the transistor of the first pixel circuit layer, and a first protecting layer on the first pixel circuit layer and covering the at least one first light-emitting diode, wherein the first protecting layer includes a first pattern from which a portion of the first protecting layer is removed, and the first pattern is spaced from the at least one first light-emitting diode in a plan view.

In one or more embodiments, the display panel may further include a second pixel circuit layer in the display area of the base layer, the second pixel circuit layer including a transistor and insulating layers, the second pixel circuit layer being spaced from the first pixel circuit layer, at least one second light-emitting diode on the second pixel circuit layer and electrically connected to the transistor of the second pixel circuit layer, a second protecting layer on the second pixel circuit layer and covering the at least one second light-emitting diode, and a connecting wire electrically connecting the transistor of the first pixel circuit layer to the transistor of the second pixel circuit layer, wherein the first protecting layer and the second protecting layer are spaced from each other.

In one or more embodiments, the second protecting layer may include a second pattern from which a portion of the second protecting layer is removed, and a proportion of volume occupied by the first pattern in the first protecting layer is the same as a proportion of volume occupied by the second pattern in the second protecting layer.

In one or more embodiments, the first pattern may have a shape of a through hole penetrating the first protecting layer in a thickness direction of the base layer.

In one or more embodiments, the first pattern may have a recess shape in which a top surface of the first protecting layer is dug in a thickness direction of the base layer.

In one or more embodiments, the display panel may further include an upper cover layer on the first protecting layer, wherein an inside of the first pattern may be filled with the upper cover layer.

In one or more embodiments, a modulus value of the first protecting layer may be greater than a modulus value of the upper cover layer.

In one or more embodiments, the first protecting layer may include SU-8.

In one or more embodiments, the first pattern may include a plurality of first sub-patterns spaced from each other in a plan view.

In one or more embodiments, the plurality of first sub-patterns may be arranged outside the first pixel circuit layer in a plan view, or may each be arranged in an area between adjacent light-emitting diodes from among the at least one first light-emitting diode.

In one or more embodiments, the first pattern may include a second sub-pattern extending along an edge of the first pixel circuit layer in a plan view.

In one or more embodiments, the at least one first light-emitting diode may include a first-first light-emitting diode and a first-second light-emitting diode, which are arranged along a first direction, and the first pattern may further include a third sub-pattern arranged in an area between the first-first light-emitting diode and the first-second light-emitting diode in a plan view and extending in a second direction intersecting the first direction.

In one or more embodiments, the second sub-pattern and the third sub-pattern may be integrated with each other.

In one or more embodiments, the at least one first light-emitting diode may include a first-first light-emitting diode and a first-second light-emitting diode, which are arranged along a first direction, and the first pattern may further include a plurality of fourth sub-patterns arranged in an area between the first-first light-emitting diode and the first-second light-emitting diode and spaced from each other in a plan view.

In one or more embodiments, the second sub-pattern and the plurality of fourth sub-patterns may be spaced from each other in a plan view.

In one or more embodiments, the display panel may further include a driving circuit layer in the non-display area of the base layer and including a transistor and insulating layers, and a peripheral protecting layer on the driving circuit layer, wherein the peripheral protecting layer may include a peripheral pattern from which a portion of the peripheral protecting layer is removed.

In one or more embodiments, a proportion of volume occupied by the first pattern in the first protecting layer may be the same as a proportion of volume occupied by the peripheral pattern in the peripheral protecting layer.

One or more embodiments of the present disclosure provides a display panel including a base layer including a display area and a non-display area around the display area, a first pixel circuit layer in the display area of the base layer and including a transistor and insulating layers, at least one first light-emitting diode on the first pixel circuit layer and electrically connected to the transistor of the first pixel circuit layer, and a first protecting layer on the first pixel circuit layer and covering the at least one first light-emitting diode, wherein a plurality of through holes penetrating the first protecting layer is in the first protecting layer, and the plurality of through holes is spaced from the at least one first light-emitting diode in a plan view.

In one or more embodiments, the display panel may further include a second pixel circuit layer in the display area of the base layer, the second pixel circuit layer including a transistor and insulating layers, the second pixel circuit layer being spaced from the first pixel circuit layer, at least one second light-emitting diode on the second pixel circuit layer and electrically connected to the transistor of the second pixel circuit layer, a second protecting layer on the second pixel circuit layer and covering the at least one second light-emitting diode, and a connecting wire electrically connecting the transistor of the first pixel circuit layer to the transistor of the second pixel circuit layer, wherein the plurality of through holes penetrating the second protecting layer may be in the second protecting layer, and a proportion of volume occupied by the plurality of through holes in the first protecting layer may be the same as a proportion of volume occupied by the plurality of through holes in the second protecting layer.

In one or more embodiments, the display panel may further include an upper cover layer arranged on the first protecting layer, the second protecting layer, and the connecting wire, wherein the upper cover layer may fill the plurality of through holes.

In one or more embodiments, the display panel may further include a driving circuit layer arranged in the non-display area of the base layer and including a transistor and insulating layers, and a peripheral protecting layer arranged on the driving circuit layer, wherein the plurality of through holes penetrating the peripheral protecting layer may be arranged in the peripheral protecting layer, and a proportion of volume occupied by the plurality of through holes in the first protecting layer may be the same as a proportion of volume occupied by the plurality of through holes in the peripheral protecting layer.

One or more embodiments of the present disclosure provides an electronic device including a display panel, and a lower cover forming an exterior and including an opening exposing a portion of the display panel on a front surface of the electronic device, wherein the display panel includes a base layer including a display area and a non-display area around the display area, a first pixel circuit layer in the display area of the base layer and including a transistor and insulating layers, at least one light-emitting diode on the first pixel circuit layer and electrically connected to the transistor of the first pixel circuit layer, and a first protecting layer on the first pixel circuit layer and covering the at least one light-emitting diode, wherein the first protecting layer includes a first pattern from which a portion of the first protecting layer is removed, and the first pattern is spaced from the at least one light-emitting diode in a plan view.

According to one or more embodiments of the present disclosure, a display panel having an improved stretchability and realizing an excellent-quality image, and an electronic device including the same may be provided. The effects, aspects, and features described above are only examples and the effects.], aspects, and features of the present disclosure are not limited to those described above.

### BRIEF DESCRIPTION OF THE DRAWINGS

FIG. 1A is a perspective view schematically showing an electronic device according to one or more embodiments of the present disclosure.

FIG. 1B is a block diagram schematically showing an electronic device according to one or more embodiments of the present disclosure.

FIG. 2 is a perspective view schematically showing a display panel according to one or more embodiments of the present disclosure.

FIGS. 3A and 3B are perspective views showing the display panel of FIG. 2 being stretched in a first direction.

FIG. 3C is a perspective view showing the display panel of FIG. 2 being stretched in a second direction.

FIG. 3D is a perspective view showing the display panel of FIG. 2 being stretched in the first direction and the second direction.

FIG. 3E is a perspective view showing the display panel of FIG. 2 being stretched in a third direction.

FIG. 4 is a plan view schematically showing a display panel according to one or more embodiments of the present disclosure.

FIG. 5 is a plan view schematically showing an arrangement of pixels of a display panel, according to one or more embodiments of the present disclosure.

FIG. 6 is a cross-sectional view schematically illustrating a portion of a display panel, according to one or more embodiments of the present disclosure.

FIGS. 7A-7C are each an equivalent circuit diagram of a pixel of a display panel, according to one or more embodiments of the present disclosure.

FIGS. 8A-8D are each a cross-sectional view schematically showing a light-emitting diode of a display panel, according to one or more embodiments of the present disclosure.

FIGS. 9A and 9B are each a plan view schematically showing a portion of a display panel, according to one or more embodiments of the present disclosure.

FIG. 10 is a cross-sectional view schematically showing a portion of a display panel, according to one or more embodiments of the present disclosure.

FIG. 11 is a diagram schematically showing a gate driving circuit of a display panel, according to one or more embodiments of the present disclosure.

FIG. 12 is a diagram schematically showing a gate driving circuit of a display panel, according to one or more embodiments of the present disclosure.

FIG. 13 is a plan view schematically showing a portion of a display panel, according to one or more embodiments of the present disclosure.

FIG. 14 is a plan view schematically showing a portion of a display panel, according to one or more embodiments of the present disclosure.

FIG. 15 is a plan view schematically showing a portion of a display panel, according to one or more embodiments of the present disclosure.

FIG. 16 is a cross-sectional view schematically showing a portion of a display panel, according to one or more embodiments of the present disclosure.

FIGS. 17A-17G are each a perspective view of an example of an electronic device including a display panel, according to one or more embodiments of the present disclosure.

### DETAILED DESCRIPTION

The present disclosure may have various modifications and various embodiments, and specific embodiments are illustrated in the drawings and are described in detail in the detailed description. Effects, aspects, and features of the embodiments of the present disclosure and methods of achieving the same will become apparent with reference to embodiments described in detail below with reference to the drawings. However, the present disclosure is not limited to the embodiments described below, and may be implemented in various forms.

Hereinafter, embodiments will be described in detail with reference to the accompanying drawings, and in the following description with reference to the drawings, like reference numerals refer to like components and redundant descriptions thereof will be omitted.

In the following embodiments, the terms “first” and “second” are not used in a limited sense and are used to distinguish one component from another component.

In the following embodiments, an expression used in the singular encompasses the expression of the plural, unless it has a clearly different meaning in the context.

In the following embodiments, it will be further understood that the terms “comprise” and/or “comprising” used herein specify the presence of stated features or components, but do not preclude the presence or addition of one or more other features or components.

In the following embodiments, when a part such as a layer, a region, or a component is referred to as being “on” or “above” another part, the part may be directly on the other part or another layer, region, or component may be present therebetween.

In the drawings, for convenience of description, sizes of components may be exaggerated or reduced. For example, because sizes and thicknesses of components in the drawings are arbitrarily illustrated for convenience of explanation, the present disclosure is not necessarily limited thereto.

When a certain embodiment may be implemented differently, a specific process order may be performed differently from the described order. For example, two consecutively described processes may be performed substantially at the same time or performed in an order opposite to the described order.

In the following embodiments, when a layer, region, component, and/or the like is connected to another layer, region, component, and/or the like, the layer, the region, the component, and/or the like may be not only directly connected thereto, but also indirectly connected thereto with an intervening layer, region, component, or the like therebetween. For example, in the specification, when a layer, region, component, and/or the like is electrically connected to another layer, region, component, and/or the like, the layer, region, component, and/or the like may be not only directly electrically connected thereto, but also indirectly electrically connected thereto with an intervening layer, region, component, and/or the like therebetween.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described in detail with reference to the accompanying drawings.

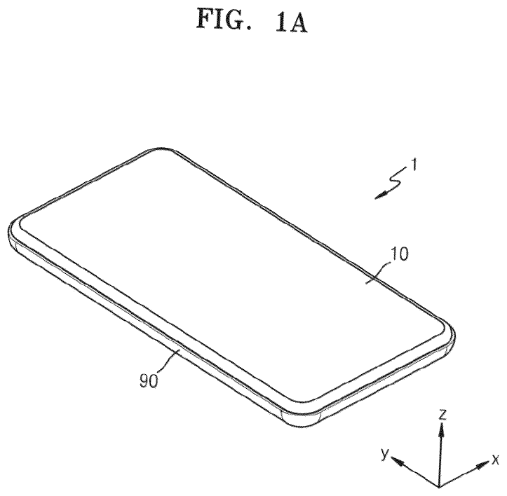

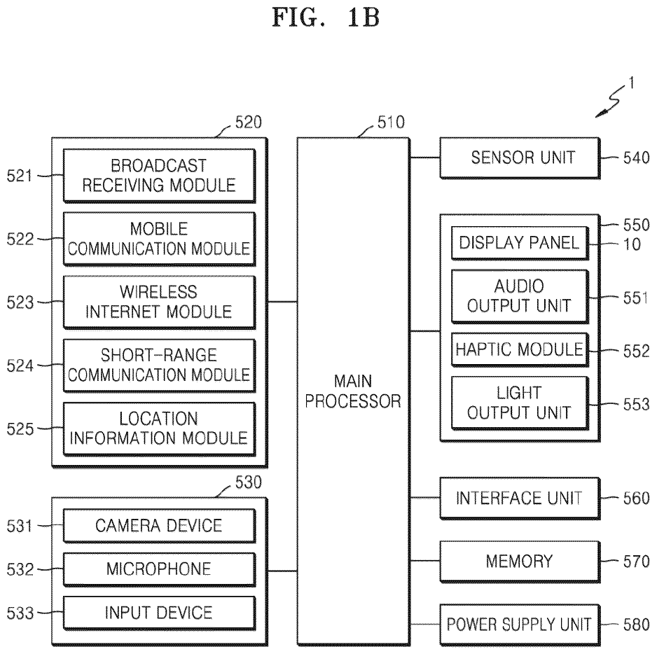

FIG. 1A is a perspective view schematically showing an electronic device 1 according to one or more embodiments of the present disclosure, and FIG. 1B is a block diagram schematically showing the electronic device 1 according to one or more embodiments of the present disclosure.

Referring to FIGS. 1A and 1B, the electronic device 1 including a display panel 10, according to one or more embodiments of the present disclosure, is a device for displaying a moving image and/or a still image, and may be used as a display screen of not only a portable electronic device, such as a mobile phone, a smartphone, a tablet personal computer (PC), a mobile communication terminal, an electronic notebook, an electronic book, a portable multimedia player (PMP), a navigation device, and/or an ultra-mobile PC (UMPC), but also various products such as a television, a laptop computer, a monitor, a billboard, and/or an Internet of things (IoT). The electronic device 1 according to one or more embodiments may be used for wearable devices, such as a smart watch, a watch phone, a glasses-type display, and/or a head mounted display (HMD). The electronic device 1 according to one or more embodiments may be used as a panel of a vehicle, a center information display (CID) arranged on a center fascia or dashboard of a vehicle, a room mirror display replacing a side mirror of a vehicle, or a display arranged on a rear surface of a front seat, as entertainment for a back seat of a vehicle.

FIG. 1A illustrates the electronic device 1 according to one or more embodiments being used as a smartphone. The electronic device 1 may include a display panel 10 and a lower cover 90 arranged below the display panel 10. The electronic device 1 may include a cover window covering a top surface of the display panel 10.

The lower cover 90 may form the exterior of the electronic device 1 and include an opening exposing a portion of the display panel 10 on a front surface of the electronic device 1. The lower cover 90 has a shape in which a surface corresponding to the display panel 10 is open, and may be assembled to the display panel 10. The lower cover 90 forms a bottom surface exterior of the electronic device 1, and a display circuit board, a component, a main circuit board, a battery, a driver, and/or the like may be arranged between the display panel 10 and the lower cover 90. The lower cover 90 may include plastic, a metal, or both plastic and a metal.

The electronic device 1 may include a main processor 510, a wireless communication unit 520, an input unit 530, a sensor unit 540, an output unit 550, an interface unit 560, a memory 570, and/or a power supply unit 580.

The main processor 510 may control all functions of the electronic device 1. For example, the main processor may output digital video data to a data driver through the display circuit board such that the display panel 10 displays an image. The main processor 510 may receive detection data from a touch sensor driving unit. The main processor 510 may determine a touch of a user according to the detection data and perform an operation corresponding to a direct touch or a proximity touch of the user. The main processor 510 may include a central processing unit, a system chip, and/or an application processor including an integrated circuit (IC).

A camera device 531 processes an image frame, such as a still image and/or a moving image, obtained by an image sensor in a camera mode, and outputs the same to the main processor 510. The camera device 531 may include at least one of a camera sensor (e.g., CCD or CMOS), a photo-sensor (or the image sensor), or a laser sensor. The camera device 531 may process an image input to the image sensor by being connected to the image sensor.

The wireless communication unit 520 may include at least one of a broadcast receiving module 521, a mobile communication module 522, a wireless Internet module 523, a short-range communication module 524, or a location information module 525.

The broadcast receiving module 521 may receive a broadcast signal and/or information related to a broadcast from an external broadcast management server through a broadcast channel. The broadcast channel may include a satellite channel or a terrestrial channel.

The mobile communication module 522 may transmit/receive a wireless signal to/from at least one of a base station, an external terminal, or a server on a mobile communication network constructed according to technical standards or communication methods for mobile communication (e.g., global system for mobile communication (GSM), code division multi access (CDMA), code division multi access 2000(CDMA 2000 ), enhanced voice-data optimized or enhanced voice-data only (EV-DO), wideband CDMA (WCDMA), high speed downlink packet access (HSDPA), high speed uplink packet access (HSUPA), long-term evolution (LTE), and/or long-term evolution-advanced (LTE-A)). The wireless signal may include various types of data according to exchange of a voice call signal, an image call signal, and/or a text/multimedia message.

The wireless Internet module 523 indicates a module for a wireless Internet access. The wireless Internet module 523 may be configured to transmit/receive the wireless signal on a communication network according to wireless Internet technologies. Examples of the wireless Internet technologies include wireless LAN (WLAN), wireless-fidelity (Wi-Fi), Wi-Fi direct, and/or digital living network alliance (DLNA).

The short-range communication module 524 is for short range communication and may support the short range communication by using at least one of Bluetooth™, radio frequency identification (RFID), infrared data association (IrDA), ultra wideband (UWB), ZigBee, near field communication (NFC)), Wi-Fi, Wi-Fi direct, or wireless universal serial bus (USB). The short-range communication module 524 may support wireless communication between the electronic device 1 and a wireless communication system, between the electronic device 1 and another electronic device, or between the electronic device 1 and a network where another electronic device (or an external server) is located, through a short-range wireless communication network (wireless area network). The short-range wireless communication network may include a short-range wireless personal communication network (wireless personal area network). Another electronic device may be a wearable device capable of exchanging (or linking) data with the electronic device 1.

The location information module 525 is a module for obtaining a location (or a current location) of the electronic device 1, and may include a global positioning system (GPS) module and/or a Wi-Fi module.

The input unit 530 may include an image input unit such as the camera device 531 for inputting an image signal, an audio input unit such as a microphone 532 for inputting an audio signal, and an input device 533 for receiving information from the user.

The camera device 531 processes an image frame, such as a still image and/or moving image, obtained by the image sensor in a video call mode and/or photographing mode. The processed image frame may be displayed on the display panel 10 and/or stored in the memory 570.

The microphone 532 processes an external audio signal to electrical voice data. The processed voice data may be variously used according to a function being performed (or an application being executed) by the electronic device 1.

The main processor 510 may control operations of the electronic device 1 to correspond to information input through the input device 533. The input device 533 may include a touch input unit or a mechanical input unit, such as a button, a dome switch, a jog wheel, and/or a jog switch, located on a rear surface or a side surface of the electronic device 1. The touch input unit may include a touchscreen layer of the display panel 10.

The sensor unit 540 may include one or more sensors configured to sense at least one of information in the electronic device 1, surrounding environment information around the electronic device 1, or user information, and generate a sensing signal corresponding thereto. The main processor 510 may, based on the sensing signal, control driving and/or operations of the electronic device 1 or perform data processing, a function, or an operation related to an application installed in the electronic device 1. The sensor unit 540 may include at least one of a proximity sensor, an illumination sensor, an acceleration sensor, a magnetic sensor, a gravity sensor (G-sensor), a gyroscope sensor, a motion sensor, a red-green-blue (RGB) sensor, an infrared (IR) sensor, a finger scan sensor, an ultrasonic sensor, an optical sensor, a battery gauge, an environment sensor (e.g., a barometer, a hydrometer, a thermometer, a radiation detecting sensor, a heat detecting sensor, or a gas detecting sensor), or a chemical sensor (e.g., an electronic nose, a healthcare sensor, or a biometrics sensor).

The output unit 550 is configured to generate an output related to visual, hearing, and/or tactile sensations, and may include at least one of the display panel 10, an audio output unit 551, a haptic module 552, or a light output unit 553.

The display panel 10 displays (outputs) information processed by the electronic device 1. For example, the display panel 10 may display execution screen information of an application driven by the electronic device 1 or user interface (UI) or graphical user interface (GUI) information according to the execution screen information. The display panel 10 may include a display layer for displaying an image and a touchscreen layer for detecting a touch input of the user. Accordingly, the display panel 10 may function as one of input devices 533 providing an input interface between the electronic device 1 and the user and at the same time, function as one of output units 550 providing an output interface between the electronic device 1 and the user.

The audio output unit 551 may output audio data received from the wireless communication unit 520 or stored in the memory 570 in a signal reception mode, a call mode, a recording mode, a voice recognition mode, or a broadcast reception mode. The audio output unit 551 may output an audio signal related to a function (for example, a call signal reception sound and/or a message reception sound) performed by the electronic device 1. The audio output unit 551 may include a receiver and a speaker. At least one of the receiver and the speaker may be an audio generating device attached to the bottom of the display panel 10 and outputting audio by vibrating the display panel 10. The audio generating device may include a piezoelectric element or piezoelectric actuator that contracts and expands in response to an electrical signal, or an exciter that generates magnetic force by using a voice coil to vibrate the display panel 10.

The haptic module 552 generates various tactile effects that may be felt by the user. The haptic module 552 may provide vibration to the user as a tactile effect. The haptic module 552 may be configured to not only deliver a tactile effect through a direct contact, but also allow the user to feel a tactile effect through muscle sense of a finger or an arm.

The light output unit 553 outputs a signal for notifying occurrence of an event by using light of a light source. Examples of an event occurred in the electronic device 1 may include message reception, call signal reception, a missed call, an alarm, a schedule remainder, email reception, and information reception through an application. A signal output by the light output unit 553 is realized as the electronic device 1 emits light of a single color or a plurality of colors through a front surface or a rear surface. A signal output may be terminated when the electronic device 1 detects that the user has identified the event.

The interface unit 560 serves as a passage with various types of external devices connected to the electronic device 1. The interface unit 560 may include at least one of a wired/wireless headset port, an external charger port, a wired/wireless data port, a memory card port, a port connecting a device including an identification module, an audio input/output (I/O) port, a video I/O port, or an earphone port. Based on an external device being connected to the interface unit 560, the electronic device 1 may perform an appropriate control related to the connected external device.

The memory 570 stores data supporting various functions of the electronic device 1. The memory 570 may store a plurality of application programs driven by the electronic device 1, and pieces of data and instructions for operations of the electronic device 1. At least some of the plurality of applications may be downloaded from an external server through wireless communication. The memory 570 may store an application for operations of the main processor 510 and temporarily store input/output data, e.g., data such as a phonebook, a message, a still image, and/or a moving image. Also, the memory 570 may store haptic data for vibration in various patterns provided to the haptic module 552, and audio data related to various types of audio provided to the audio output unit 551. The memory 570 may include at least one type of storage medium from among a flash memory type, a hard disk type, a solid state disk (SSD) type, a silicon disk drive (SDD) type, a multimedia card micro type, or card-type memory (e.g., a secure digital or extreme digital (XD) memory), random access memory (RAM), static RAM (SRAM), read-only memory (ROM), electrically erasable programmable ROM (EEPROM), programmable ROM (PROM), a magnetic memory, a magnetic disk, and/or an optical disk.

The power supply unit 580 supplies power to each component included in the electronic device 1 by receiving external power or internal power, under control by the main processor 510. The power supply unit 580 may include a battery. Also, the power supply unit 580 may include a connecting port and the connecting port may be configured as an example of the interface unit 560 to which an external charger supplying power is electrically connected to charge the battery. Alternatively, the power supply unit 580 may be configured to charge the battery in a wireless manner without having to use the connecting port.

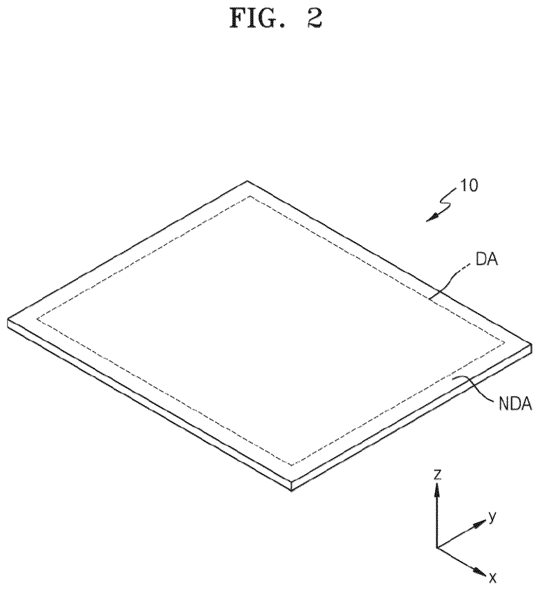

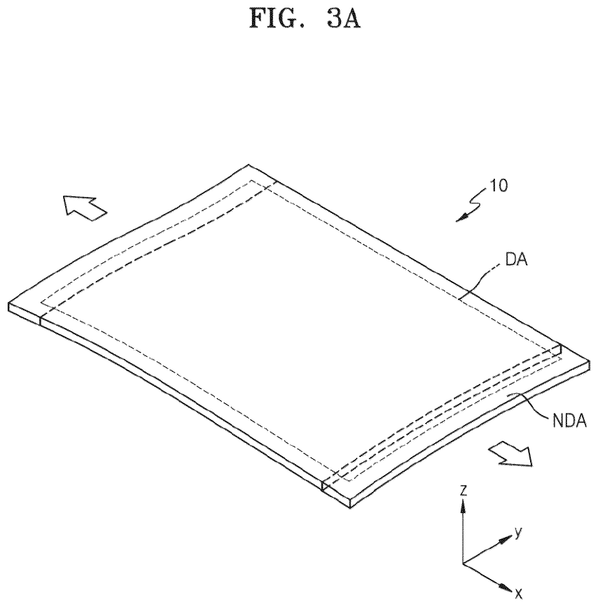

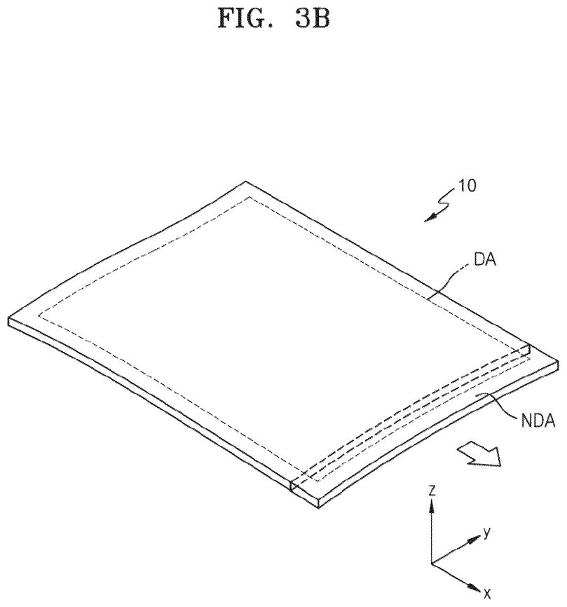

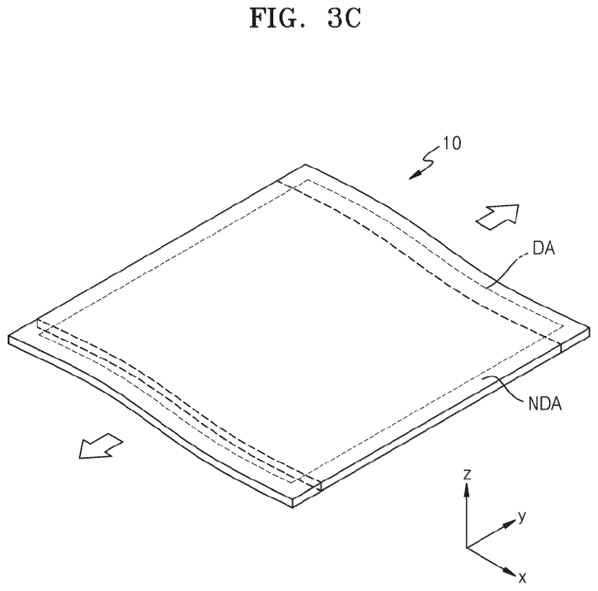

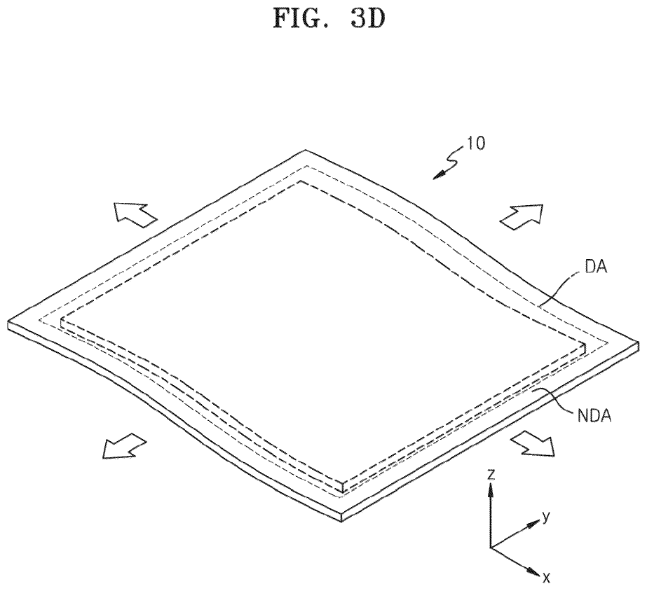

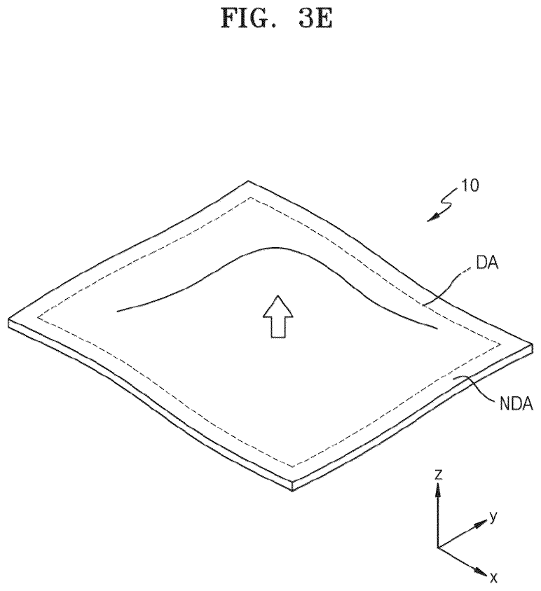

FIG. 2 is a perspective view schematically showing the display panel 10 according to one or more embodiments of the present disclosure. FIGS. 3A and 3B are perspective views showing the display panel 10 of FIG. 2 being stretched in a first direction. FIG. 3C is a perspective view showing the display panel 10 of FIG. 2 being stretched in a second direction. FIG. 3D is a perspective view showing the display panel 10 of FIG. 2 being stretched in the first direction and the second direction. FIG. 3E is a perspective view showing the display panel 10 of FIG. 2 being stretched in a third direction.

Referring to FIG. 2, the display panel 10 may include a display area DA and a non-display area NDA disposed around the display area DA along an edge or a periphery of the display area DA. The display area DA may include a plurality of pixels. The display panel 10 may provide a certain image by using light emitted from the plurality of pixels. The non-display area NDA may be arranged outside the display area DA. The non-display area NDA may entirely surround the display area DA.

The display panel 10 may be stretched and contracted in various directions. The display panel 10 may be stretched in the first direction (e.g., an x direction and/or a −x direction) by external force applied by an external object or the user. According to one or more embodiments, as shown in FIGS. 3A and 3B, the display area DA and/or the non-display area NDA of the display panel 10 may be stretched in the first direction (e.g., the x direction and/or the −x direction). For example, the display panel 10 may be stretched along the x direction and the −x direction as shown in FIG. 3A, or along the x direction while one side of the display panel 10 is fixed as shown in FIG. 3B.

The display panel 10 may be stretched in the second direction (e.g., a y direction and/or a −y direction) by external force applied by the external object or the user. For example, as shown in FIG. 3C, the display area DA and/or the non-display area NDA of the display panel 10 may be stretched in the y direction and the −y direction. According to one or more embodiments, the display panel 10 may be stretched in the y direction or the −y direction while one side of the display panel 10 is fixed.

The display panel 10 may be stretched in a plurality of directions, e.g., the first direction (e.g., the x direction and/or the −x direction) and the second direction (e.g., the y direction and/or the-y direction), by external force applied by the external object or a part of the body of a person. As shown in FIG. 3D, the display area DA and/or the non-display area NDA of the display panel 10 may be stretched in the ±x direction and the ±y direction.

The display panel 10 may be stretched in the third direction (e.g., a z direction or a −z direction) by external force applied by the external object or the part of the body of the person. According to one or more embodiments, FIG. 3E illustrates a portion of the display panel 10, for example, a partial area of the display area DA, protruding in the z direction. According to one or more embodiments, a portion of the display panel 10, for example, a partial area of the display area DA, may protrude along the z direction (or be dented along the −z direction).

In FIGS. 3A-3E , the display panel 10 is stretched in the first direction, the second direction, and/or the third direction, but the present disclosure is not limited thereto. According to one or more embodiments, the display panel 10 may be variously transformed in an atypical shape, for example, may be bent or twisted with two or more axes.

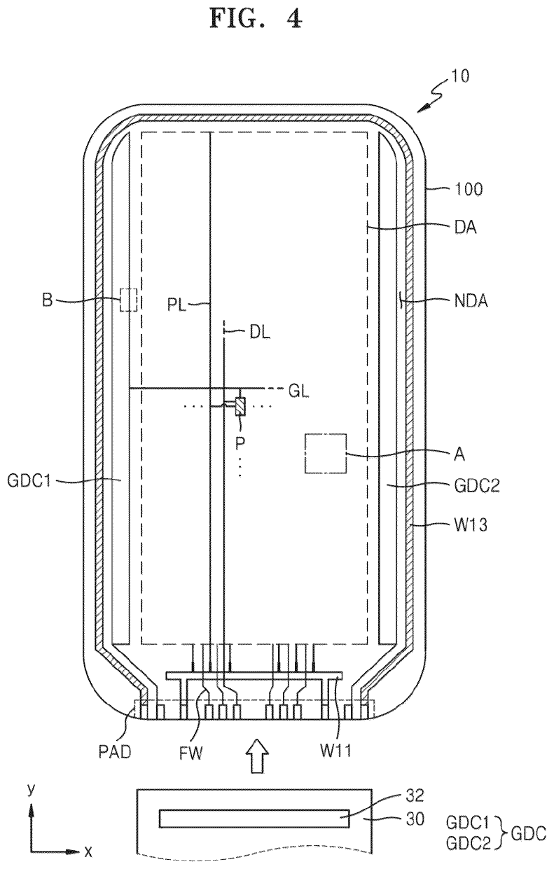

FIG. 4 is a plan view schematically showing the display panel 10 according to one or more embodiments of the present disclosure.

Referring to FIG. 4, the display panel 10 may include the display area DA and the non-display area NDA surrounding the display area DA. Pixels P are arranged in the display area DA of a substrate 100. The pixels P may each display an image by using light emitted from a light-emitting element, such as a light-emitting diode. Each light-emitting diode may emit, for example, red, green, or blue light.

Each light-emitting diode may be electrically connected to a pixel circuit and each pixel circuit may include transistors and a storage capacitor. Each pixel circuit may be electrically connected to peripheral circuits and peripheral wires arranged in the non-display area NDA. The peripheral circuits arranged in the non-display area NDA may include a gate driving circuit GDC and a terminal portion PAD. The peripheral wires may include a driving voltage supply wire W11, a common voltage supply wire W13, and a fanout wire FW.

The gate driving circuit GDC may include drivers configured to provide electrical signals respectively to gate electrodes of the transistors electrically connected to the light-emitting elements. In detail, the gate driving circuit GDC may apply a scan signal to each of the pixel circuits respectively corresponding to the pixels P, through a gate line GL.

The gate driving circuit GDC may include a first gate driving circuit GDC1 and a second gate driving circuit GDC2, which are arranged on opposite sides with the display area DA therebetween. The second gate driving circuit GDC2 may be located on an opposite side of the first gate driving circuit GDC1, based on the display area DA, and may be approximately parallel to the first gate driving circuit GDC1. Some of the pixel circuits may be electrically connected to the first gate driving circuit GDC1 and the remainders thereof may be electrically connected to the second gate driving circuit GDC2. According to one or more embodiments, the second gate driving circuit GDC2 may be omitted.

The terminal portion PAD may be arranged at one side of the substrate 100. The terminal portion PAD may not be covered by an insulating layer, but may be exposed to be connected to a display circuit board 30. A display driving unit 32 may be arranged on the display circuit board 30. The display driving unit 32 may generate a control signal transmitted to the first gate driving circuit GDC1 and the second gate driving circuit GDC2. The display driving unit 32 may generate a data signal, and the generated data signal may be transmitted to the pixel circuits of the pixels P via the fanout wire FW and a data line DL connected to the fanout wire FW.

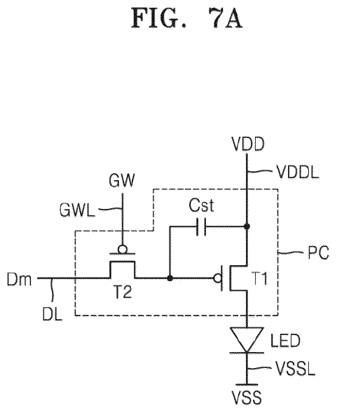

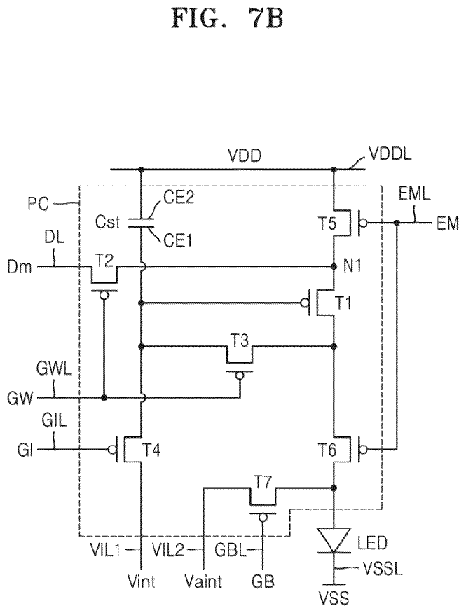

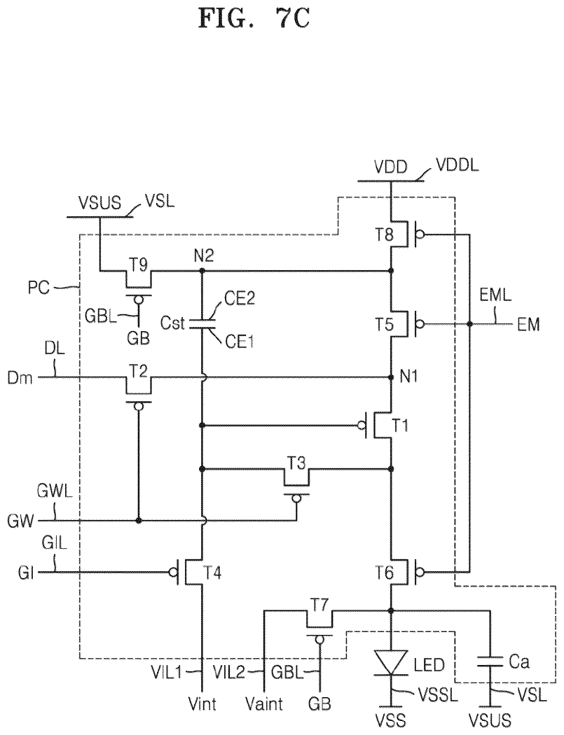

The display driving unit 32 may supply a first power voltage VDD (FIG. 7A) to the driving voltage supply wire W11 or supply a second power voltage VSS (FIG. 7A) to the common voltage supply wire W13. The first power voltage VDD (FIG. 7A) may be applied to the pixel circuit of the pixel P through a driving voltage line PL connected to the driving voltage supply wire W11, and the second power voltage VSS (FIG. 7A) may be connected to the common voltage supply wire W13 and applied to an opposing electrode of the light-emitting element. The driving voltage supply wire W11 may extend from a lower side of the display area DA in the x direction. The common voltage supply wire W13 may have a loop shape with one open side, and partially surround the display area DA.

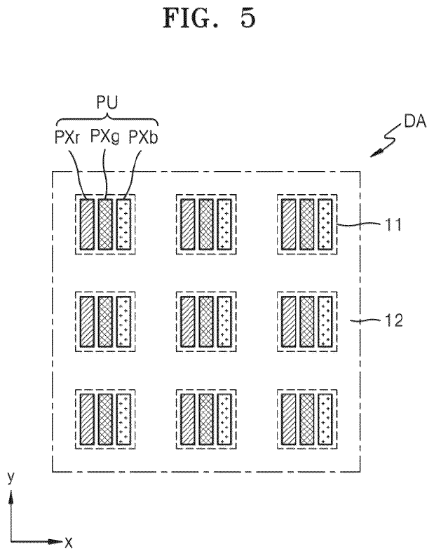

FIG. 5 is a plan view schematically showing an arrangement of pixels of a display panel, according to one or more embodiments of the present disclosure.

Referring to FIG. 5, the display area DA may include first areas 11 and a second area 12 surrounding each of the first areas 11. The first areas 11 may be repeatedly arranged along the first direction (e.g., the x direction) and the second direction (e.g., the y direction).

The display area DA may include the first area 11 and the second area 12, which have different elongations. For example, the display panel 10 may include the first area 11 having a relatively small elongation and the second area 12 having a relatively large elongation. In the specification, the elongation is a value that represents a change (ΔL/L) in a length by which the display panel 10 is stretchable without physical damage to the display panel 10 when external force is applied to the display panel 10. Here, ΔL denotes the amount of change in the length of the display panel 10 and L denotes the initial length of the display panel 10. Accordingly, the elongations of the first area 11 and the second area 12 may indicate changes in lengths of the first area 11 and the second area 12, respectively, when the same external force is applied to the first area 11 and the second area 12.

The elongation of the first area 11 being smaller than the elongation of the second area 12 may indicate that deformation of the first area 11 occurs relatively less by external force. Accordingly, the first area 11 may be referred to as a low deformation area and the second area 12 may be referred to as a high deformation area.

The first areas 11 may be spaced (e.g., spaced apart) from each other and arranged two-dimensionally in the display area DA. The first area 11 may be an area where the pixels are arranged and accordingly, the first area 11 may be referred to as a pixel area or an emission area. One or more pixels may be arranged in each first area 11. The first area 11 may include a pixel unit PU including a group of pixels and each pixel unit PU may include a red pixel PXr, a green pixel PXg, and a blue pixel PXb.

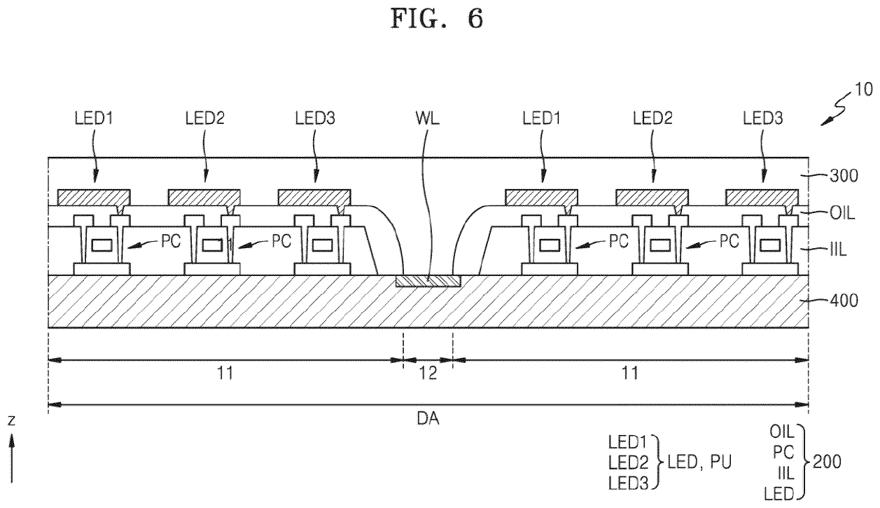

The second area 12 may be located between adjacent first areas 11. As shown in FIG. 5, in a plan view, the second area 12 may have a shape surrounding each of the first areas 11. The second area 12 may be an area where the connecting wire passes through, wherein the connecting wire is for connecting pixel circuits PC (FIG. 6) arranged in two adjacent first areas 11.

FIG. 6 is a cross-sectional view schematically illustrating a portion of a display panel, according to one or more embodiments of the present disclosure.

Referring to FIG. 6, the display area DA may include the first area 11 and the second area 12, and the second area 12 may be an area connecting the first areas 11 that are arranged adjacent to each other. The first area 11 has an elongation relatively smaller than the second area 12 and may include a light-emitting diode LED and a pixel circuit PC. The second area 12 is an area in which an elongation is relatively greater than the first area 11 and may include a connecting wire WL included in a signal line supplying a signal to each pixel circuit PC.

The first area 11 and the second area 12 may be arranged in a base layer 400. In other words, the base layer 400 may be defined by the first area 11 and the second area 12. The light-emitting diode LED and the pixel circuit PC may be arranged in the first area 11 of the base layer 400, and the connecting wire WL may be arranged in the second area 12 of the base layer 400.

The base layer 400 may absorb stress that may be generated when the display panel 10 is elongated. The base layer 400 may include elastic polymer. For example, the base layer 400 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), or ecoflex.

A display layer 200 may be arranged in the first area 11 of the base layer 400. The display layer 200 may include an inorganic insulating stack IIL, the pixel circuit PC, an organic insulating layer OIL, and the light-emitting diode LED. The pixel circuit PC may be arranged on the base layer 400 and the inorganic insulating stack IIL may be arranged between electrodes included in the pixel circuit PC. The organic insulating layer OIL may be arranged on the inorganic insulating stack IIL to cover the pixel circuit PC. The light-emitting diode LED may be arranged on the organic insulating layer OIL and may be electrically connected to the corresponding pixel circuit PC. The inorganic insulating stack IIL may include an inorganic insulating material such as silicon nitride and/or silicon oxide, and the organic insulating layer OIL may include an organic insulating material such as polyimide.

According to one or more embodiments, one pixel unit PU may be arranged in one first area 11. As described above, the pixel unit PU may include the red pixel PXr (FIG. 5), the green pixel PXg (FIG. 5), and the blue pixel PXb (FIG. 5). The red pixel PXr (FIG. 5) may include a first light-emitting diode LED1, the green pixel PXg (FIG. 5) may include a second light-emitting diode LED2, and the blue pixel PXb may include a third light-emitting diode LED3. For example, the first light-emitting diode LED1 may emit red light, the second light-emitting diode LED2 may emit green light, and the third light-emitting diode LED3 may emit blue light. According to one or more embodiments, the light-emitting diode LED may emit white light.

The connecting wire WL may be arranged in the second area 12 of the base layer 400. According to one or more embodiments, as shown in FIG. 6, the connecting wire WL may be arranged on the base layer 400 while being arranged relatively lower than the display layer 200. In other words, the base layer 400 may be arranged to cover the connecting wire WL arranged on a rear surface of the display layer 200. Accordingly, a thickness of the base layer 400 corresponding to the second area 12 may be less than a thickness of the base layer 400 corresponding to the first area 11. However, the present disclosure is not limited thereto, and according to one or more other embodiments, the connecting wire WL may be arranged on the base layer 400 while being arranged substantially in a same layer as some layers of the display layer 200.

The connecting wire WL may include a material having both excellent stretchability and excellent electrical characteristics. According to one or more embodiments, the connecting wires WL arranged in the second area 12 may include a liquid metal. According to one or more other embodiments, the connecting wires WL may include a metal nanostructure and elastic polymer. According to one or more embodiments, the connecting wires WL may include a conductive composite material including an elastomer.

According to one or more embodiments, an upper cover layer 300 may be arranged on the light-emitting diode LED. The upper cover layer 300 may be arranged in all of the first area 11 and the second area 12. In other words, the upper cover layer 300 may be arranged to cover the entire display area DA. The upper cover layer 300 may cover the light-emitting diode LED and the connecting wire WL. The upper cover layer 300 may absorb stress that may be generated when the display panel 10 is elongated. In detail, the upper cover layer 300 may prevent the stress that may be generated when the display panel 10 is elongated from being transferred to the light-emitting diode LED and the pixel circuit PC.

The upper cover layer 300 may include elastic polymer. The upper cover layer 300 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, or polydimethylsiloxane (PDMS). According to one or more embodiments, the upper cover layer 300 may include a same material as the base layer 400. However, the present disclosure is not limited thereto, and the upper cover layer 300 may include a different material from the base layer 400.

FIGS. 7A-7C are each an equivalent circuit diagram of a pixel of a display panel, according to one or more embodiments of the present disclosure.

Referring to FIG. 7A, the light-emitting diode LED corresponding to a pixel may be electrically connected to the pixel circuit PC, and the pixel circuit PC may include a first transistor T1, a second transistor T2, and a storage capacitor Cst. The pixel circuit PC may be electrically connected to a signal line and a voltage line. The signal line may include the gate line GL (FIG. 4) such as a scan signal line GWL, and the data line DL, and the voltage line may include a first voltage line VDDL. Here, the first voltage line VDDL may be connected to the driving voltage supply wire W11 (FIG. 4) and a second voltage line VSSL may be connected to the common voltage supply wire W13 (FIG. 4).

The second transistor T2 may be electrically connected to the scan signal line GWL and the data line DL. The scan signal line GWL may provide a scan signal GW to a gate electrode of the second transistor T2. The second transistor T2 may transmit, to the first transistor T1, a data signal Dm input from the data line DL, according to the scan signal GW input from the scan signal line GWL.

The storage capacitor Cst may be electrically connected to the second transistor T2 and the first voltage line VDDL, and store a voltage corresponding to a difference between a voltage received from the second transistor T2 and the first power voltage VDD supplied by the first voltage line VDDL.

The first transistor T1 is a driving transistor and may control a driving current flowing through the light-emitting diode LED. The first transistor T1 may be connected to the first voltage line VDDL, the light-emitting diode LED, and the storage capacitor Cst. The first transistor T1 may control the driving current flowing through the light-emitting diode LED from the first voltage line VDDL, in response to a value of a voltage stored in the storage capacitor Cst. The light-emitting diode LED may emit light of a certain luminance according to the driving current. A first electrode of the light-emitting diode LED may be electrically connected to the first transistor T1, and a second electrode thereof may be electrically connected to the second voltage line VSSL supplying the second power voltage VSS.

In FIG. 7A, the pixel circuit PC includes two transistors and one storage capacitor, but according to one or more other embodiments, the pixel circuit PC may include three or more transistors.

Referring to FIG. 7B, the pixel circuit PC may include the first transistor T1, the second transistor T2, a third transistor T3, a fourth transistor T4, a fifth transistor T5, a sixth transistor T6, a seventh transistor T7, and the storage capacitor Cst.

The pixel circuit PC is electrically connected to signal lines and voltage lines. The signal lines may include the gate lines GL (FIG. 4) such as the scan signal line GWL, a bypass control line GBL, an initialization control line GIL, and an emission control line EML, and the data line DL. The voltage lines may include a first initialization voltage line VIL1, a second initialization voltage line VIL2, and the first voltage line VDDL. Here, the first voltage line VDDL may be connected to the driving voltage supply wire W11 (FIG. 4) and the second voltage line VSSL may be connected to the common voltage supply wire W13 (FIG. 4).

The first voltage line VDDL may transmit the first power voltage VDD to the first transistor T1. The first initialization voltage line VIL1 may transmit, to the pixel circuit PC, a first initialization voltage Vint for initializing the first transistor T1. The second initialization voltage line VIL2 may transmit, to the pixel circuit PC, a second initialization voltage Vaint for initializing the first electrode of the light-emitting diode LED.

The first transistor T1 may be electrically connected to the first voltage line VDDL via the fifth transistor T5, and electrically connected to the light-emitting diode LED via the sixth transistor T6. The first transistor T1 operates as a driving transistor and supplies a driving current to the light-emitting diode LED by receiving the data signal Dm according to a switching operation of the second transistor T2.

The second transistor T2 is a data write transistor and electrically connected to the scan signal line GWL and the data line DL. The second transistor T2 is electrically connected to the first voltage line VDDL via the fifth transistor T5. The second transistor T2 is turned on according to the scan signal GW received through the scan signal line GWL to perform a switching operation of transmitting the data signal Dm transmitted to the data line DL, to a first node N1 connected to the first transistor T1.

The third transistor T3 is electrically connected to the scan signal line GWL and electrically connected to the light-emitting diode LED via the sixth transistor T6. The third transistor T3 may be turned on according to the scan signal GW received through the scan signal line GWL and diode-connect the first transistor T1.

The fourth transistor T4 is a first initialization transistor and is electrically connected to the initialization control line GIL and the first initialization voltage line VIL1. The fourth transistor T4 may be turned on according to an initialization control signal GI received through the initialization control line GIL to initialize a voltage of the gate electrode of the first transistor T1 by transmitting the first initialization voltage Vint from the first initialization voltage line VIL1 to the gate electrode of the first transistor T1. The initialization control signal GI may correspond to a scan signal from another pixel circuit arranged in a previous row of the corresponding pixel circuit PC.

The fifth transistor T5 may be an operation control transistor and the sixth transistor T6 may be an emission control transistor. The fifth transistor T5 and the sixth transistor T6 may be electrically connected to the emission control line EML and concurrently (e.g., simultaneously) turned on according to an emission control signal EM received through the emission control line EML, thereby forming a current path for the driving current to flow in a direction from the first voltage line VDDL to the light-emitting diode LED.

The seventh transistor T7 is a second initialization transistor and may be electrically connected to the bypass control line GBL, the second initialization voltage line VIL2, the sixth transistor T6, and the light-emitting diode LED. The seventh transistor T7 is turned on according to a bypass control signal GB received through the bypass control line GBL, and may initialize the first electrode of the light-emitting diode LED by transmitting the second initialization voltage Vaint from the second initialization voltage line VIL2 to the first electrode of the light-emitting diode LED.

The storage capacitor Cst includes a first electrode CE1 and a second electrode CE2. The first electrode CE1 is electrically connected to the gate electrode of the first transistor T1 and the second electrode CE2 is electrically connected to the first voltage line VDDL. The storage capacitor Cst may maintain a voltage applied to the gate electrode of the first transistor T1 by storing and maintaining a voltage corresponding to a difference between opposite end voltages of the first voltage line VDDL and the gate electrode of the first transistor T1.

Referring to FIG. 7C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel circuit PC is electrically connected to signal lines and voltage lines. The signal lines may include the gate lines GL (FIG. 4) such as the scan signal line GWL, the bypass control line GBL, the initialization control line GIL, and the emission control line EML, and the data line DL. The voltage lines may include the first initialization voltage line VIL1, the second initialization voltage line VIL2, a sustain voltage line VSL, and the first voltage line VDDL. Here, the first voltage line VDDL may be connected to the driving voltage supply wire W11 (FIG. 4) and the second voltage line VSSL may be connected to the common voltage supply wire W13 (FIG. 4).

The first voltage line VDDL may transmit the first power voltage VDD to the first transistor T1. The first initialization voltage line VIL1 may transmit, to the pixel circuit PC, the first initialization voltage Vint for initializing the first transistor T1. The second initialization voltage line VIL2 may transmit, to the pixel circuit PC, the second initialization voltage Vaint for initializing the first electrode of the light-emitting diode LED. The sustain voltage line VSL may provide a sustain voltage VSUS to a second node N2, for example, the second electrode CE2 of the storage capacitor Cst, during an initialization period and a data write period.

The first transistor T1 may be electrically connected to the first voltage line VDDL via the fifth transistor T5 and the eighth transistor T8, and electrically connected to the light-emitting diode LED via the sixth transistor T6. The first transistor T1 operates as a driving transistor and may supply the driving current to the light-emitting diode LED by receiving the data signal Dm according to a switching operation of the second transistor T2.

The second transistor T2 is electrically connected to the scan signal line GWL and the data line DL, and electrically connected to the first voltage line VDDL via the fifth transistor T5 and the eighth transistor T8. The second transistor T2 is turned on according to the scan signal GW received through the scan signal line GWL to perform a switching operation of transmitting the data signal Dm transmitted to the data line DL, to the first node N1 connected to the first transistor T1.

The third transistor T3 is electrically connected to the scan signal line GWL and electrically connected to the light-emitting diode LED via the sixth transistor T6. The third transistor T3 is turned on according to the scan signal GW received through the scan signal line GWL and may compensate for a threshold voltage of the first transistor T1 by diode-connecting the first transistor T1.

The fourth transistor T4 may be connected to the initialization control line GIL and the first initialization voltage line VIL1, and turned on according to the initialization control signal GI received through the initialization control line GIL to transmit the first initialization voltage Vint from the first initialization voltage line VIL1 to the gate electrode of the first transistor T1, thereby initializing a voltage of the gate electrode of the first transistor T1. The initialization control signal GI may correspond to a scan signal from another pixel circuit arranged in a previous row of the corresponding pixel circuit PC.

The fifth transistor T5, the sixth transistor T6, and the eighth transistor T8 may be electrically connected to the emission control line EML and concurrently (e.g., simultaneously) turned on according to the emission control signal EM received through the emission control line EML, thereby forming a current path for the driving current to flow in a direction from the first voltage line VDDL to the light-emitting diode LED.

The seventh transistor T7 is the second initialization transistor and may be electrically connected to the bypass control line GBL, the second initialization voltage line VIL2, the sixth transistor T6, and the light-emitting diode LED. The seventh transistor T7 is turned on according to the bypass control signal GB received through the bypass control line GBL, and initializes the first electrode of the light-emitting diode LED by transmitting the second initialization voltage Vaint from the second initialization voltage line VIL2 to the first electrode of the light-emitting diode LED.

The ninth transistor T9 may be electrically connected to the bypass control line GBL, the second electrode CE2 of the storage capacitor Cst, and the sustain voltage line VSL. The ninth transistor T9 may be turned on according to the bypass control signal GB received through the bypass control line GBL and transmit the sustain voltage VSUS to the second node N2, for example, the second electrode CE2 of the storage capacitor Cst, in the initialization period and the data write period.

The eighth transistor T8 and the ninth transistor T9 may be each electrically connected to the second node N2, for example, the second electrode CE2 of the storage capacitor Cst. According to one or more embodiments, the eighth transistor T8 may be turned off and the ninth transistor T9 may be turned on in the initialization period and the data write period, and the eighth transistor T8 may be turned on and the ninth transistor T9 may be turned off in an emission period. The sustain voltage VSUS is transmitted to the second node N2 in the initialization period and the data write period, and thus, uniformity (e.g., long range uniformity (LRU)) of luminance of a display device according to a voltage drop of the first voltage line VDDL may be enhanced.

The storage capacitor Cst includes the first electrode CE1 and the second electrode CE2. The first electrode CE1 is electrically connected to the gate electrode of the first transistor T1 and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting diode LED. The auxiliary capacitor Ca stores and maintains a voltage corresponding to a voltage difference between the first electrode of the light-emitting diode LED and the sustain voltage line VSL while the seventh transistor T7 and the ninth transistor T9 are turned on, thereby preventing an increase in black luminance when the sixth transistor T6 is turned off.

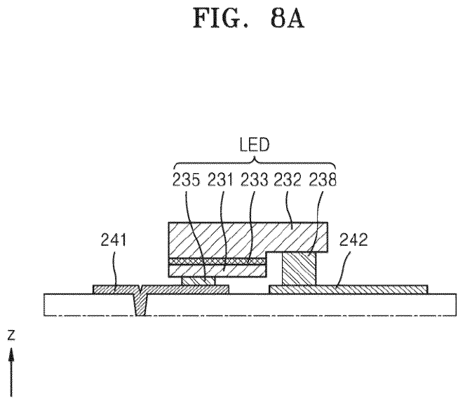

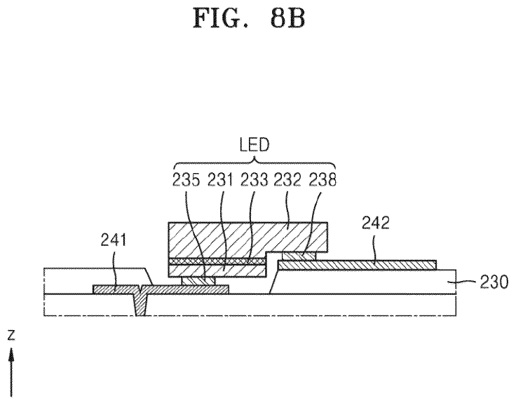

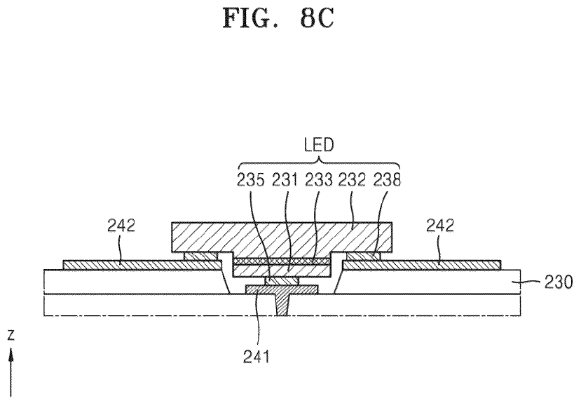

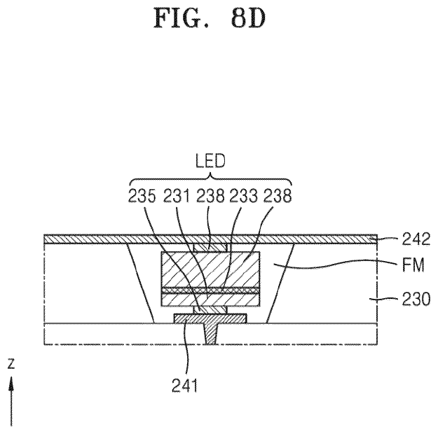

FIGS. 8A-8D are each a cross-sectional view schematically showing a light-emitting diode of a display panel, according to one or more embodiments of the present disclosure.

Referring to FIG. 8A, a light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be electrically connected to a first electrode pad 241 and a second electrode pad 242, which are arranged in a same layer, respectively. The second electrode pad 242 may be a portion of the second voltage line VSSL (FIG. 7A) or a conductive layer electrically connected to the second voltage line VSSL (FIG. 7A).

According to one or more embodiments, the first semiconductor layer 231 may include a p-type semiconductor layer. The p-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and/or AlInN, and a p-type dopant, such as Mg, Zn, Ca, Sr, and/or Ba, may be doped.

The second semiconductor layer 232 may include, for example, an n-type semiconductor layer. The n-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and/or AlInN, and/or an n-type dopant, such as Si, Ge, and/or Sn, may be doped.

The intermediate layer 233 is a region where electrons and holes recombine, and when the electrons and holes recombine, the intermediate layer 233 may transit to a low energy level and generate light having a corresponding wavelength. The intermediate layer 233 may include, for example, a semiconductor material having a composition formula of InₓAl_{y}Ga_{1-x-y}N (0≤x≤1, 0≤y≤1, 0≤x+y≤1), and may have a single quantum well structure or a multi quantum well (MQW) structure. Also, the intermediate layer 233 may have a quantum wire structure or a quantum dot structure.

In FIG. 8A, the first semiconductor layer 231 includes the p-type semiconductor layer and the second semiconductor layer 232 includes the n-type semiconductor layer, but the present disclosure is not limited thereto. According to one or more other embodiments, the first semiconductor layer 231 may include the n-type semiconductor layer and the second semiconductor layer 232 may include the p-type semiconductor layer.

In FIG. 8A, the first electrode pad 241 and the second electrode pad 242 are arranged in a same layer, but the present disclosure is not limited thereto. Referring to FIG. 8B, the first electrode pad 241 and the second electrode pad 242 may be arranged in different layers. For example, a bank layer 230 including an opening overlapping at least a portion of the first electrode pad 241 may be arranged on the first electrode pad 241, and the second electrode pad 242 may be arranged on a top surface of the bank layer 230. A structure of the light-emitting diode LED shown in FIG. 8B is the same as that described above with reference to FIG. 8A.

According to one or more other embodiments, as shown in FIG. 8C, the second electrode pad 242 may be arranged on opposite sides based on the first electrode pad 241 in a cross-sectional view. The bank layer 230 may include an opening overlapping at least a portion of the first electrode pad 241, and the second electrode pad 242 may be arranged on the bank layer 230 around the opening of the bank layer 230. According to one or more embodiments, in a plan view, the second electrode pad 242 may have a closed loop shape entirely surrounding the opening of the bank layer 230 and/or the first electrode pad 241. A structure of the light-emitting diode LED shown in FIG. 8C is the same as that described above with reference to FIG. 8A.

In FIGS. 8A-8C , the first electrode 235 and the second electrode 238 of the light-emitting diode LED face a same direction (e.g., a downward direction, a −z direction), but the present disclosure is not limited thereto. As shown in FIG. 8D, the first electrode 235 and the second electrode 238 of the light-emitting diode LED may face opposite directions.

The bank layer 230 includes an opening exposing at least a portion of the first electrode pad 241, and a thickness of the bank layer 230 may be substantially the same as a thickness of the light-emitting diode LED. The opening of the bank layer 230 may be filled with a filling material FM, and the second electrode pad 242 may be arranged on the top surface of the bank layer 230 to be electrically connected to (e.g., in contact with) the second electrode 238 of the light-emitting diode LED. The filling material FM may be an organic material having insulating properties.

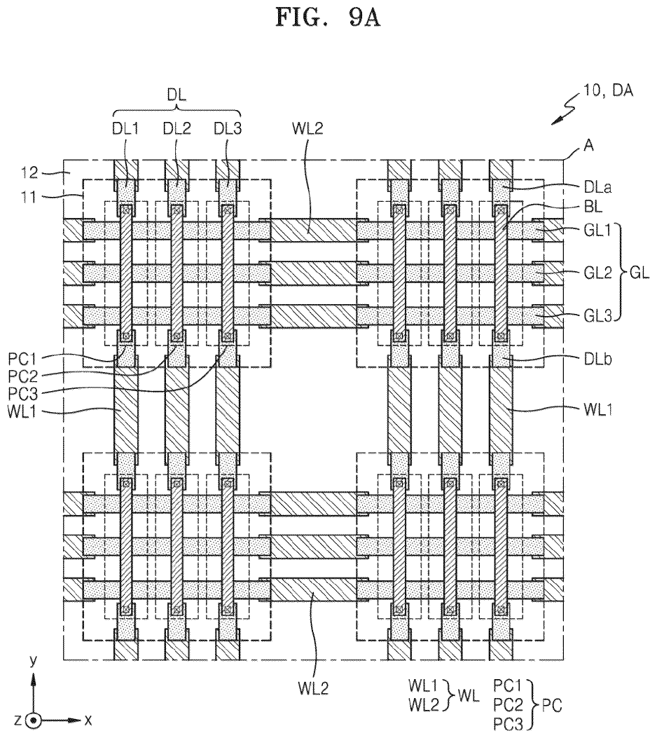

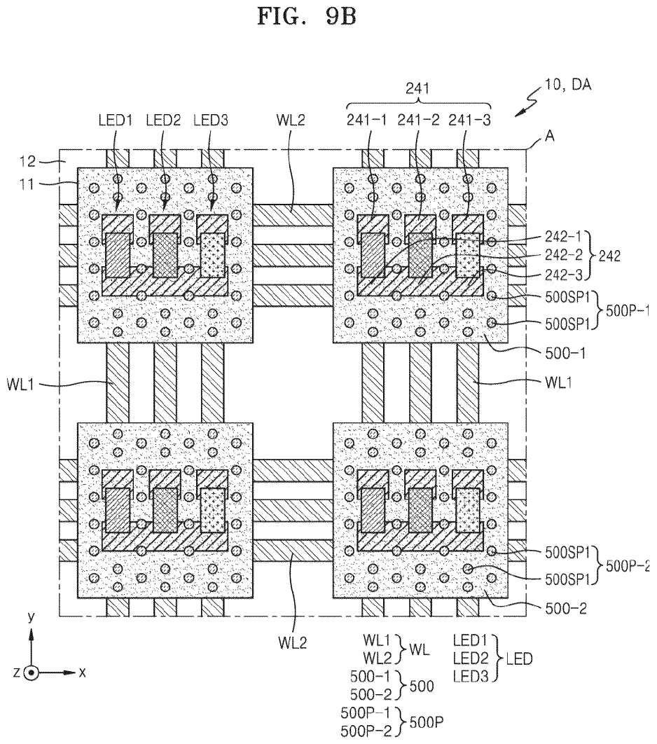

FIGS. 9A and 9B are each a plan view schematically showing a portion of a display panel, according to one or more embodiments of the present disclosure. FIGS. 9A and 9B are each a plan view schematically showing a region A of the display panel 10 of FIG. 4.

First, referring to FIG. 9A, the display area DA may include the plurality of first areas 11 and the second area 12 around (e.g., surrounding) the plurality of first areas 11. The first area 11 may have a smaller elongation than the second area 12. Accordingly, when the display panel 10 is stretched, the first area 11 may be deformed less than the second area 12. As described above, the first area 11 may be referred to as a low deformation area (or a low deformation portion). Also, the first area 11 is an area where light-emitting diodes are arranged, and may be referred to as a pixel area or an emission area.

The second area 12 may surround the first area 11 and have a larger elongation than the first area 11. The second area 12 may be an area that is mainly deformed according to stretching of a display device. The second area 12 is arranged between the plurality of first areas 11 and may be referred to as a connecting portion that connects the first areas 11. Also, the second area 12 may be referred to as a main deformation area (or a main deformation portion) or a high deformation area (or a high deformation portion). The second area 12 is an area where a light-emitting diode is not arranged among the display area DA and may be referred to as a non-pixel area or a non-emission area.

The pixel circuit PC for driving the light-emitting diode of each pixel may be arranged in the first area 11. For example, a first pixel circuit PC1 of the red pixel PXr (FIG. 5), a second pixel circuit PC2 of the green pixel PXg (FIG. 5), and a third pixel circuit PC3 of the blue pixel PXb (FIG. 5) may be arranged in the first area 11. Each of the first pixel circuit PC1, the second pixel circuit PC2, and the third pixel circuit PC3 may include at least one transistor and a capacitor like the pixel circuit PC described with reference to FIGS. 7A-7C .

Lines electrically connected to the pixel circuit PC may be arranged in the display area DA. The lines may include a voltage line or a signal line. According to one or more embodiments, FIG. 9A illustrates the gate line GL and the data line DL arranged in the first area 11. The gate line GL and the data line DL may each be electrically connected to the pixel circuit PC through a contact hole.

The gate line GL of FIG. 9A is a line providing a gate signal to a gate electrode of the transistor. According to one or more embodiments, the gate line GL may include a first gate line GL1, a second gate line GL2, and a third gate line GL3. The first to third gate lines GL1 to GL3 extending in the first direction (e.g., the x direction) may be respectively connected to the pixel circuits PC arranged in a same row and transmit different gate signals. For example, the gate line GL of FIG. 9A may include the scan signal line GWL, the bypass control line GBL, the initialization control line GIL, and/or the emission control line EML of FIG. 7B-7C .

The data line DL of FIG. 9A is a line providing a data signal to respective pixel circuits PC. The data line DL extending in the second direction (e.g., the y direction) may be electrically connected to the pixel circuits PC arranged in a same column. According to one or more embodiments, the data line DL may include a first data line DL1 electrically connected to the first pixel circuit PC1, a second data line DL2 electrically connected to the second pixel circuit PC2, and a third data line DL3 electrically connected to the third pixel circuit PC3.

Two adjacent signal lines respectively arranged in two adjacent first areas 11 may be electrically connected to each other by the connecting wire WL. In detail, two adjacent data lines DL respectively arranged in two adjacent first areas 11 may be electrically connected to each other by a first connecting wire WL1 (or a vertical connecting wire). The first connecting wire WL1 may be arranged in the second area 12 and extend in the second direction (e.g., the y direction). The data lines DL arranged on opposite sides with the first connecting wire WL1 therebetween may each be connected to the first connecting wire WL1.

Two adjacent gate lines GL respectively arranged in two adjacent first areas 11 may be electrically connected to each other by a second connecting wire WL2 (or a horizontal connecting wire). The second connecting wire WL2 may be arranged in the second area 12 and extend in the first direction (e.g., the x direction). The gate lines GL arranged on opposite sides with the second connecting wire WL2 therebetween may each be connected to the second connecting wire WL2.

The gate line GL and the data line DL may cross each other in the first area 11. According to one or more embodiments, the data line DL may include a first portion DLa and a second portion DLb, which are separated from each other with the gate line GL therebetween, and a bridge line BL arranged between the first portion DLa and the second portion DLb. The first portion DLa and the second portion DLb may be electrically connected to each other by the bridge line BL.

The bridge line BL may be arranged in an area where the data line DL and the gate line GL cross each other, and may connect the first portion DLa and the second portion DLb of the data line DL to each other. The bridge line BL may be arranged in a layer different from the first portion DLa and the second portion DLb. One end of the bridge line BL may be connected to the first portion DLa through a contact hole and the other end of the bridge line BL may be connected to the second portion DLb through the contact hole (e.g., another contact hole).

Although FIG. 9A illustrates the data line DL being connected through the first portion DLa, the second portion DLb, and the bridge line BL, but the present disclosure is not limited thereto. According to one or more other embodiments, the gate line GL may be divided into a first portion and a second portion, which are connected through a bridge line.

The first connecting wire WL1 and the second connecting wire WL2 arranged in the second area 12 may stretch better than the gate line GL and the data line DL arranged in the first area 11. Elongations of the first connecting wire WL1 and the second connecting wire WL2 may be greater than elongations of the gate line GL and the data line DL.

The gate line GL and the data line DL may each include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). According to one or more embodiments, the gate line GL and the data line DL may each include a single layer or a plurality of layers including the above-described metal. According to one or more embodiments, the gate line GL and the data line DL may each include a metal thin-film including a triple layer of a Ti/Al/Ti structure.

The first connecting wire WL1 and the second connecting wire WL2 may include a liquid metal or a conductive composite material including a metal nanostructure, elastic polymer, and/or elastomer. Accordingly, when the display panel 10 is elongated, the first connecting wire WL1, the second connecting wire WL2, and the second area 12 may be highly deformed.

FIG. 9A illustrates the gate line GL and the data line DL being electrically connected to the first connecting wire WL1 and the second connecting wire WL2, respectively, but the present disclosure is not limited thereto. According to one or more other embodiments, the first initialization voltage line VIL1, the second initialization voltage line VIL2, the sustain voltage line VSL, the first voltage line VDDL, and/or the second voltage line VSSL described above in FIGS. 7A-7C may be arranged in the first area 11 and electrically connected to the connecting wire WL arranged in the second area 12.

Next, referring to FIG. 9B, at least one light-emitting element may be arranged in the first area 11. According to one or more embodiments, FIG. 9B illustrates the light-emitting elements arranged in the first area 11 including the first light-emitting diode LED1, the second light-emitting diode LED2, and the third light-emitting diode LED3, which emit light of different colors. For example, one of the first to third light-emitting diodes LED1 to LED3 may emit red light, another one may emit green light, and the remaining one may emit blue light.

According to one or more embodiments, FIG. 9B illustrates three light-emitting diodes LED arranged in the first area 11 and three first electrode pads 241 respectively corresponding to the light-emitting diodes LED, but the present disclosure is not limited thereto. According to one or more other embodiments, two or at least four light-emitting diodes LED may be arranged in the first area 11, and two or at least four first electrode pads 241 may be arranged in the first area 11. Hereinafter, for convenience of description, it is described that three light-emitting diodes LED and three first electrode pads 241 are arranged in the first area 11.

Each light-emitting diode LED may be electrically connected to the pixel circuit PC through the first electrode pad 241, and electrically connected to the second voltage line VSSL (FIG. FIG. 7A) that is a common voltage line through the second electrode pad 242.

The first electrode pads 241 may be spaced (e.g., spaced apart) from each other in one direction (e.g., the x direction). In this regard, FIG. 9B illustrates the first electrode pads 241 including a 1st-1 electrode pad 241-1, a 1st-2 electrode pad 241-2, and a 1st-3 electrode pad 241-3. The 1st-1 electrode pad 241-1, the 1st-2 electrode pad 241-2, and the 1st-3 electrode pad 241-3 may be spaced (e.g., spaced apart) from each other in the first direction (e.g., the x direction). The 1st-1 electrode pad 241-1 and the 1st-3 electrode pad 241-3 may be arranged on opposite sides with the 1st-2 electrode pad 241-2 therebetween. The 1st-1 electrode pad 241-1, the 1st-2 electrode pad 241-2, and the 1st-3 electrode pad 241-3 may electrically connected to the first pixel circuit PC1, the second pixel circuit PC2, and the third pixel circuit PC3, respectively, through the contact hole (e.g., through respective contact holes).

The second electrode pad 242 may be spaced (e.g., spaced apart) from the first electrode pads 241 in a direction intersecting an arrangement direction of the first electrode pads 241, e.g., the second direction (e.g., the y direction). The second electrode pad 242 may be electrically connected to the second voltage line VSSL (FIG. 7A) passing through the first area 11 through the contact hole (e.g., through a respective contact hole). The light-emitting elements may share one second electrode pad 242. For example, a first portion 242-1 of the second electrode pad 242 may be electrically connected to the first light-emitting diode LED1, a second portion 242-2 of the second electrode pad 242 may be electrically connected to the second light-emitting diode LED2, and a third portion 242-3 of the second electrode pad 242 may be electrically connected to the third light-emitting diode LED3. Here, the first portion 242-1, the second portion 242-2, and the third portion 242-3 may be integrally connected to each other. The second portion 242-2 of the second electrode pad 242 may be located between the first portion 242-1 and the third portion 242-3.

The first portion 242-1 of the second electrode pad 242 may be arranged adjacent to one of the first electrode pads 241, e.g., the 1st-1 electrode pad 241-1, in the second direction (e.g., the y direction). The second portion 242-2 of the second electrode pad 242 may be arranged adjacent to another one of the first electrode pads 241, e.g., the 1st-2 electrode pad 241-2, in the second direction (e.g., the y direction). The third portion 242-3 of the second electrode pad 242 may be arranged adjacent to the remaining one of the first electrode pads 241, e.g., the 1st-3 electrode pad 241-3, in the second direction (e.g., the y direction).

According to one or more embodiments, a protecting layer 500 may be arranged on the light-emitting diode LED. The protecting layer 500 may be arranged in the first area 11 and protect the light-emitting elements by covering the first light-emitting diode LED1, the second light-emitting diode LED2, and the third light-emitting diode LED3 arranged in the first area 11. The protecting layer 500 may prevent damage to the light-emitting diode LED and prevent the light-emitting diode LED from being detached from the display panel 10.

The protecting layer 500 may be patterned in the first area 11. The plurality of protecting layers 500 may be arranged in the display panel 10 as one protecting layer 500 is patterned in one first area 11. In other words, the plurality of protecting layers 500 may be spaced (e.g., spaced apart) from each other with the second area 12 therebetween. For example, the protecting layer 500 may include a first protecting layer 500-1 and a second protecting layer 500-2, which are spaced (e.g., spaced apart) from each other as shown in FIG. 9B.

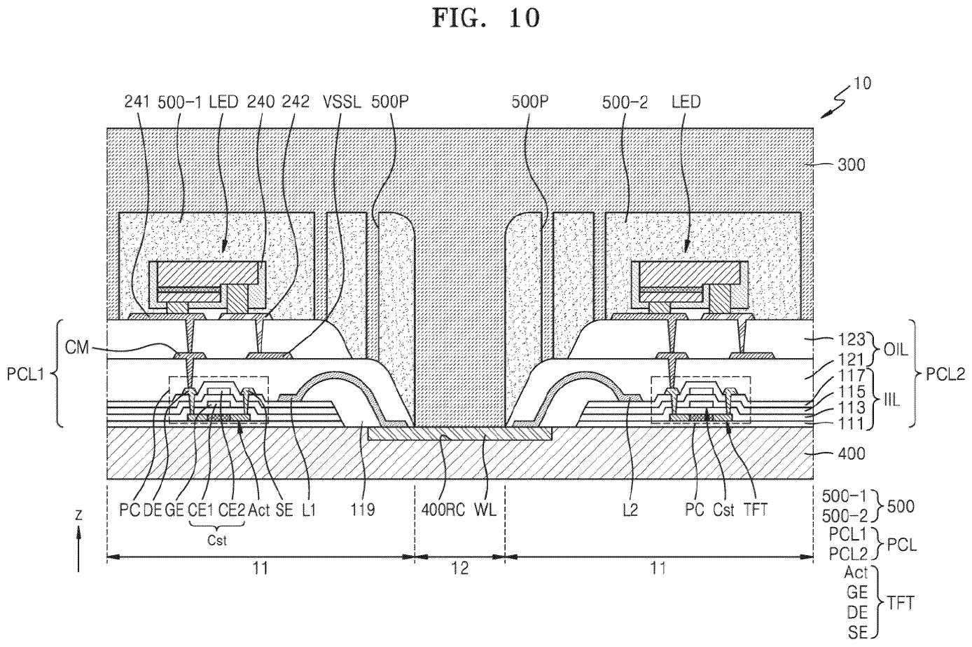

The protecting layer 500 may be arranged on the light-emitting diode LED to protect the light-emitting diode LED, and thus may include a material that is transparent and has a greater modulus value than the upper cover layer 300 (FIG. 10). According to one or more embodiments, the protecting layer 500 may include SU-8. However, the present disclosure is not limited thereto, and the protecting layer 500 may include a material that is transparent and has high modulus, such as polyimide, polycarbonate, or polymethyl methacrylate (PMMA). For example, when the protecting layer 500 includes SU-8, modulus of the protecting layer 500 may have a value in a range of 2.0 GPa to 5.0 GPa.

According to one or more embodiments, the protecting layer 500 may include a pattern 500P from which a portion of the protecting layer 500 is removed. For example, the first protecting layer 500-1 may include a first pattern 500P-1 from which a portion of the first protecting layer 500-1 is removed, and the second protecting layer 500-2 may include a second pattern 500P-2 from which a portion of the second protecting layer 500-2 is removed. As will be described in detail with reference to FIG. 10, the pattern 500P of the protecting layer 500 may have the shape of a through hole penetrating the protecting layer 500. When the pattern 500P having the shape of the through hole is formed in the protecting layer 500 and the upper cover layer 300 (FIG. 10) described below is filled in the pattern 500P, a physical coupling force between the upper cover layer 300 (FIG. 10) and a lower structure may be increased.

According to one or more embodiments, the pattern 500P of the protecting layer 500 may include a plurality of first sub-patterns 500SP1 spaced (e.g., spaced apart) from each other in a plan view. The plurality of first sub-patterns 500SP1 may each have the shape of a through hole penetrating the protecting layer 500. In this regard, as shown in FIG. 9B, the plurality of first sub-patterns 500SP1 may have the shape of a circle in a plan view. However, the present disclosure is not limited thereto, and the plurality of first sub-patterns 500SP1 may have the shape of a polygon or the shape of an oval in a plan view.

According to one or more embodiments, the pattern 500P of the protecting layer 500 may be spaced (e.g., spaced apart) from the light-emitting diode LED in a plan view. This is to prevent an optical characteristic from being changed due to a difference in a refractive index when the pattern 500P of the protecting layer 500 is arranged on the light-emitting diode LED as the upper cover layer 300 (FIG. 10) is filled in the pattern 500P of the protecting layer 500. In other words, the pattern 500P of the protecting layer 500 may not overlap the light-emitting diode LED.

In detail, in one or more embodiments, the plurality of first sub-patterns 500SP1 may be arranged outside the first area 11 in a plan view. In other words, the plurality of first sub-patterns 500SP1 may be around (e.g., may surround) the plurality of light-emitting diodes LED arranged in the first area 11. Also, the plurality of first sub-patterns 500SP1 may be arranged in an area between the light-emitting diodes LED adjacent to each other in a plan view. For example, the plurality of first sub-patterns 500SP1 may be arranged in an area between the first light-emitting diode LED1 and the second light-emitting diode LED2 and an area between the second light-emitting diode LED2 and the third light-emitting diode LED3.

As described above, the first protecting layer 500-1 may include the first pattern 500P-1 from which a portion of the first protecting layer 500-1 is removed, and the second protecting layer 500-2 may include the second pattern 500P-2 from which a portion of the second protecting layer 500-2 is removed. According to one or more embodiments, a proportion of the volume occupied by the first pattern 500P-1 in the first protecting layer 500-1 may be the same as a proportion of the volume occupied by the second pattern 500P-2 in the second protecting layer 500-2. In other words, a proportion of the volume occupied by the plurality of through holes in the first protecting layer 500-1 may be the same as a proportion of the volume occupied by the plurality of through holes in the second protecting layer 500-2. Simply, a pattern density of the first pattern 500P-1 may be the same as a pattern density of the second pattern 500P-2. According to one or more embodiments, the pattern 500P may be formed such that the plurality of protecting layers 500 arranged in the display area DA have a same uniform pattern density.

For example, the volume of one first sub-pattern 500SP1 arranged in the first protecting layer 500-1 may be the same as the volume of one first sub-pattern 500SP1 arranged in the second protecting layer 500-2, and the number of first sub-patterns 500SP1 arranged in the first protecting layer 500-1 may be the same as the number of first sub-patterns 500SP1 arranged in the second protecting layer 500-2. However, the present disclosure is not limited thereto, and the patterns 500P of the protecting layers 500 may have different shapes and arrangements as long as the volumes of the patterns 500P included in the protecting layers 500 are the same.

When the patterns 500P are formed such that the plurality of protecting layers 500 have a uniform pattern density, the volume of the upper cover layer 300 (FIG. 10) filled in the through holes of the protecting layers 500 may also be uniformly maintained. Accordingly, the physical coupling force between the upper cover layer 300 (FIG. 10) and the lower structure may be uniformly improved in the display area DA, and mechanical stability of the display panel 10 may be promoted. In addition, because the upper cover layer 300 (FIG. 10) includes a material having a relatively lower modulus than the protecting layer 500, an elongation property of the display panel 10 may also be uniformly improved in the display area DA.

FIG. 10 is a cross-sectional view schematically showing a portion of a display panel, according to one or more embodiments of the present disclosure.

Referring to FIG. 10, as described above with reference to FIGS. 9A and 9B, the display panel 10 may include the first areas 11 and the second area 12 between the first areas 11. Because the components of the display panel 10 are arranged on the base layer 400, the display panel 10 including the first area 11 and the second area 12 may correspond to the base layer 400 including the first area 11 and the second area 12.

The display panel 10 may include a pixel circuit layer PCL arranged in each of the two adjacent first areas 11, and the light-emitting diode LED on the pixel circuit layer PCL. The light-emitting diode LED shown in FIG. 10 may correspond to one of the first to third light-emitting diodes LED1 to LED3 (e.g., a first-first LED, a first-second LED, and a first-third LED) shown in FIG. 9B.

Each pixel circuit layer PCL may include the inorganic insulating stack IIL, the pixel circuit PC, and the organic insulating layer OIL. Hereinafter, for convenience of description, one of the pixel circuit layers PCL respectively arranged in the two adjacent first areas 11 will be referred to as a first pixel circuit layer PCL1 and the other one will be referred to as a second pixel circuit layer PCL2.

The first pixel circuit layer PCL1 and the second pixel circuit layer PCL2 may each be arranged on the base layer 400. The first pixel circuit layer PCL1 and the second pixel circuit layer PCL2 may each be arranged on a first surface (e.g., a top surface) of the base layer 400.

The base layer 400 may absorb stress generated when the display panel 10 is elongated. The base layer 400 may include elastic polymer. The base layer 400 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), or ecoflex.

The first pixel circuit layer PCL1 and the second pixel circuit layer PCL2 may each include the inorganic insulating stack IIL, the pixel circuit PC, and the organic insulating layer OIL. The inorganic insulating stack IIL may include a buffer layer 111, a gate insulating layer 113, a first interlayer insulating layer 115, and a second interlayer insulating layer 117. The organic insulating layer OIL may include a first organic insulating layer 121 and a second organic insulating layer 123.

The first pixel circuit layer PCL1 and the second pixel circuit layer PCL2 may be spaced (e.g., spaced apart) from each other. The first pixel circuit layer PCL1 and the second pixel circuit layer PCL2 being spaced (e.g., spaced apart) from each other may indicate that the inorganic insulating stack IIL, the pixel circuit PC, and the organic insulating layer OIL of the first pixel circuit layer PCL1 are respectively spaced (e.g., spaced apart) from the inorganic insulating stack IIL, the pixel circuit PC, and the organic insulating layer OIL of the second pixel circuit layer PCL2.

The inorganic insulating stack IIL may be arranged in the first area 11 and not arranged in the second area 12. The inorganic insulating stack IIL may have an isolated shape in the first area 11. The inorganic insulating stacks IIL respectively arranged in the first areas 11 may be spaced (e.g., spaced apart) from each other in a plan view. For example, the buffer layer 111, the gate insulating layer 113, the first interlayer insulating layer 115, and the second interlayer insulating layer 117 of the first pixel circuit layer PCL1 may be respectively separated from the buffer layer 111, the gate insulating layer 113, the first interlayer insulating layer 115, and the second interlayer insulating layer 117 of the second pixel circuit layer PCL2.

Similarly, the organic insulating layer OIL may be arranged in the first area 11 and not arranged in the second area 12. The organic insulating layer OIL may have an isolated shape in the first area 11. For example, the first organic insulating layer 121 and the second organic insulating layer 123 of the first pixel circuit layer PCL1 may be respectively separated from the first organic insulating layer 121 and the second organic insulating layer 123 of the second pixel circuit layer PCL2.

The buffer layer 111 may be arranged on the base layer 400 and the pixel circuit PC may be arranged on the buffer layer 111. The buffer layer 111 may include an inorganic insulating material such as silicon oxide, silicon nitride, and/or silicon oxynitride.

A thin-film transistor TFT of the pixel circuit PC may include a semiconductor layer Act, a gate electrode GE, a source electrode SE, and a drain electrode DE. FIG. 10 illustrates a top-gate type in which the gate electrode GE is arranged on the semiconductor layer Act with the gate insulating layer 113 therebetween, but according to another embodiment, the thin-film transistor TFT may be a bottom-gate type.

The semiconductor layer Act may include polysilicon. Alternatively, the semiconductor layer Act may include amorphous silicon, an oxide semiconductor, and/or an organic semiconductor. The gate electrode GE may include a metal thin-film including a low-resistance metal material. The gate electrode GE may include a conductive material including molybdenum (Mo), aluminum (Al), copper (Cu), and/or titanium (Ti), and may be formed in a multi-layer or single layer including the conductive material. For example, the gate electrode GE may include a metal thin-film including a triple layer of a Ti/Al/Ti structure.

The gate insulating layer 113 between the semiconductor layer Act and the gate electrode GE may include an inorganic insulating material such as silicon oxide, silicon nitride, silicon oxynitride, aluminum oxide, and/or titanium oxide. The gate insulating layer 113 may be a single layer or multi-layer including the material described above.

The source electrode SE and the drain electrode DE may be located in a same layer, e.g., on the second interlayer insulating layer 117, and include a same material. The source electrode SE and the drain electrode DE may include a metal thin-film including a low-resistance metal material. The source electrode SE and the drain electrode DE may include a conductive material including molybdenum (Mo), aluminum (Al), copper (Cu), and/or titanium (Ti), and may be formed in a multi-layer or single layer including the conductive material. For example, like the gate electrode GE, the source electrode SE and the drain electrode DE may include a metal thin-film including a triple layer of a Ti/Al/Ti structure. The second interlayer insulating layer 117 may include an inorganic insulating material such as silicon oxide, silicon nitride, silicon oxynitride, aluminum oxide, and/or titanium oxide, and may be a single layer or multi-layer including the material described above.

The storage capacitor Cst may include the first electrode CE1 and the second electrode CE2, which overlap each other with the first interlayer insulating layer 115 therebetween. The storage capacitor Cst may overlap the thin-film transistor TFT. In this regard, FIG. 10 illustrates that the gate electrode GE of the thin-film transistor TFT is the first electrode CE1 of the storage capacitor Cst. According to one or more embodiments, the storage capacitor Cst may not overlap the thin-film transistor TFT. The storage capacitor Cst may be covered by the second interlayer insulating layer 117.

The first interlayer insulating layer 115 may be arranged between the gate insulating layer 113 and the second interlayer insulating layer 117. The first interlayer insulating layer 115 and the second interlayer insulating layer 117 may each include an inorganic insulating material such as silicon oxide, silicon nitride, silicon oxynitride, aluminum oxide, and/or titanium oxide, and may each be a single layer or multi-layer including the material described above.

The second electrode CE2 of the storage capacitor Cst may include a conductive material and may be formed in a single layer or a multi-layer. The second electrode CE2 may include a metal thin-film including a low-resistance metal material. The second electrode CE2 may include a conductive material including molybdenum (Mo), aluminum (Al), copper (Cu), and/or titanium (Ti), and may be formed in a multi-layer or single layer including the conductive material. For example, the second electrode CE2 may include a metal thin-film including a triple layer of a Ti/Al/Ti structure.

The first organic insulating layer 121 may be arranged on the second interlayer insulating layer 117 covering the source electrode SE and the drain electrode DE. The second organic insulating layer 123 may be arranged on the first organic insulating layer 121. A connecting electrode CM and the second voltage line VSSL may be arranged on the first organic insulating layer 121. The connecting electrode CM may electrically connect the pixel circuit PC to the first electrode pad 241. The second voltage line VSSL may be electrically connected to the second electrode pad 242.

The connecting electrode CM and the second voltage line VSSL may include a metal thin-film including a low-resistance metal material. The connecting electrode CM and the second voltage line VSSL may include a conductive material including molybdenum (Mo), aluminum (Al), copper (Cu), and/or titanium (Ti), and may be formed in a multi-layer or single layer including the conductive material. For example, the connecting electrode CM and the second voltage line VSSL may include a metal thin-film including a triple layer of a Ti/Al/Ti structure.

The first electrode pad 241 and the second electrode pad 242 may be arranged on the second organic insulating layer 123. The first electrode pad 241 may be electrically connected to the thin-film transistor TFT through the connecting electrode CM between the first organic insulating layer 121 and the second organic insulating layer 123.

The light-emitting diode LED (e.g., a first LED on PCL1, and a second LED on PCL2) on the first electrode pad 241 and the second electrode pad 242 may be the same as the light-emitting diode LED described above with reference to FIG. 8A. According to one or more embodiments, the light-emitting diode LED may have a structure as shown in FIG. 8B. One surface of the light-emitting diode LED may be covered by a sub-protecting layer 240 including an organic insulating material.

A first line L1 may be a signal line or a voltage line electrically connected to the pixel circuit PC of the first pixel circuit layer PCL1. A second line L2 may be a signal line or a voltage line electrically connected to the pixel circuit PC of the second pixel circuit layer PCL2. According to one or more embodiments, the first line L1 and the second line L2 may include the gate line GL (FIG. 9A) or the data line DL (FIG. 9A) described above with reference to FIG. 9A. According to another embodiment, the first line L1 and the second line L2 may be the first voltage line VDDL or the second voltage line VSSL described with reference to FIG. 7A, or may be the first initialization voltage line VIL1, the second initialization voltage line VIL2, the sustain voltage line VSL, the first voltage line VDDL, or the second voltage line VSSL described with reference to FIGS. 7B and 7C.

Each of the first line L1 and the second line L2 may be arranged on the second interlayer insulating layer 117 and extend towards the connecting wire WL. A portion of the first line L1 may be located on the corresponding second interlayer insulating layer 117. Another portion of the first line L1 may pass through the organic insulating stack OIL and extend over the connecting wire WL to be in direct contact with the connecting wire WL. In the third direction (e.g., the z direction), the portion of the first line L1 may be located between the second interlayer insulating layer 117 and the first organic insulating layer 121, and the other portion of the first line L1 may be located between a third organic insulating layer 119 described below and the first organic insulating layer 121. Similarly, a portion of the second line L2 may be located on the corresponding second interlayer insulating layer 117, and another portion of the second line L2 may extend over the connecting wire WL to be in direct contact with the connecting wire WL. In the third direction (e.g., the z direction), the portion of the second line L2 may be located between the second interlayer insulating layer 117 and the first organic insulating layer 121, and the other portion of the second line L2 may be located between the third organic insulating layer 119 described below and the first organic insulating layer 121.

The inorganic insulating stack IIL in an isolated shape in a plan view may form a step with respect to the top surface of the base layer 400, as shown in FIG. 10. According to one or more embodiments, as shown in FIG. 10, the organic insulating layer OIL may further include the third organic insulating layer 119 arranged to cover a side surface of the inorganic insulating stack IIL. The third organic insulating layer 119 may have a closed loop shape in a plan view to cover the side surface of the inorganic insulating stack IIL. For example, the first line L1 and the second line L2 may extend over the connecting wire WL across a top surface of the corresponding third organic insulating layer 119.

As described above, the connecting wire WL may be arranged in the second area 12. According to one or more embodiments, the connecting wire WL may be arranged on a bottom surface of the pixel circuit layer PCL. In other words, the base layer 400 may include a recess 400RC concave from the top surface to the bottom surface, and the connecting wire WL may be located in the recess 400RC.

The connecting wire WL includes a first surface (e.g., a bottom surface) facing the base layer 400, and a second surface (e.g., a top surface) opposite to the first surface. The second surface (e.g., the top surface) of the connecting wire WL may be located in a same surface as the top surface of the base layer 400. Accordingly, a thickness of the base layer 400 overlapping the connecting wire WL may be less than a thickness of another portion of the base layer 400, which does not overlap the connecting wire WL. In other words, when the connecting wire WL has a structure embedded in the base layer 400, the base layer 400 may absorb stress that may be focused on the connecting wire WL when the display panel 10 is elongated.

The light-emitting diode LED may be arranged on the corresponding pixel circuit layer PCL. For example, the light-emitting diode LED electrically connected to the pixel circuit PC of the first pixel circuit layer PCL1 may be arranged on the corresponding first pixel circuit layer PCL1, and the light-emitting diode LED electrically connected to the pixel circuit PC of the second pixel circuit layer PCL2 may be arranged on the corresponding second pixel circuit layer PCL2.

According to one or more embodiments, the protecting layer 500 covering the light-emitting diode LED may be arranged on the pixel circuit layer PCL. For example, the first protecting layer 500-1 covering the light-emitting diode LED on the first pixel circuit layer PCL1 may be arranged on the first pixel circuit layer PCL1, and the second protecting layer 500-2 covering the light-emitting diode LED on the second pixel circuit layer PCL2 may be arranged on the second pixel circuit layer PCL2.

Like the first pixel circuit layer PCL1 and the second pixel circuit layer PCL2 being spaced (e.g., spaced apart) from each other, the first protecting layer 500-1 and the second protecting layer 500-2 may also be spaced (e.g., spaced apart) from each other. In other words, the protecting layer 500 may be arranged only in the first area 11 and not arranged in the second area 12. As shown in FIG. 10, the protecting layer 500 may cover an entire surface of the pixel circuit layer PCL. However, the present disclosure is not limited thereto, and the protecting layer 500 may cover only a portion of the pixel circuit layer PCL.

The upper cover layer 300 may be arranged on the first protecting layer 500-1 and the second protecting layer 500-2. The upper cover layer 300 may cover all top surfaces of the first area 11 and second area 12 of the display panel 10. For example, the upper cover layer 300 may not only cover the protecting layer 500, but also cover the top surface of the connecting wire WL. The upper cover layer 300 may absorb stress that may be transferred to the light-emitting diode LED and the connecting wire WL during elongation, and may flatten the top surface of the display panel 10.

The upper cover layer 300 may include elastic polymer. For example, the upper cover layer 300 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), or ecoflex.

According to one or more embodiments, a modulus of the protecting layer 500 may have a value greater than a modulus of the upper cover layer 300. For example, when the protecting layer 500 may include SU-8, and in this case, the protecting layer 500 may have a value (e.g., modulus) in a range of 2.0 GPa to 5.0 GPa. By arranging, on the light-emitting diode LED, the protecting layer 500 including a material having a relatively greater modulus value than the upper cover layer 300, a coupling force between the light-emitting diode LED and the pixel circuit layer PCL may be increased and detachment of the light-emitting diode LED may be prevented.

As described above, the protecting layer 500 may include the pattern 500P from which a portion of the protecting layer 500 is removed. As shown in FIG. 10, the pattern 500P of the protecting layer 500 may have the shape of a through hole penetrating the protecting layer 500. In other words, the pattern 500P of the protecting layer 500 may expose a top surface of the pixel circuit layer PCL arranged below the protecting layer 500. The upper cover layer 300 may be arranged on the protecting layer 500, and thus, the pattern 500P of the protecting layer 500 may be filled with the upper cover layer 300. In other words, the upper cover layer 300 may be arranged in the plurality of through holes (e.g., 500P) formed in the protecting layer 500.

As described above, when the pattern 500P is formed in the protecting layer 500 and the upper cover layer 300 is filled inside the pattern 500P, the physical coupling force between the upper cover layer 300 and the lower structure (e.g., the pixel circuit layer PCL) may be increased and the mechanical stability of the display panel 10 may be improved. For example, when the upper cover layer 300 is arranged directly on the pixel circuit layer PCL, a coupling force between the upper cover layer 300 and the pixel circuit layer PCL is weak, and thus, the upper cover layer 300 is unable to absorb stress when the display panel 10 is elongated and the stress may be applied to the pixel circuit layer PCL, causing a defect such as a crack. On the other hand, as shown in FIG. 10, when the pattern 500P is formed in the protecting layer 500 strongly fixed to the pixel circuit layer PCL and the upper cover layer 300 is filled in the pattern 500P, a contact area between the upper cover layer 300 and the protecting layer 500 may be increased, thereby efficiently improving the physical coupling force between the upper cover layer 300 and the lower structure.

Also, because the protecting layer 500 and the upper cover layer 300 have different refractive indexes, when the pattern 500P of the protecting layer 500 overlaps the light-emitting diode LED, light emitted from the light-emitting diode LED may have different optical characteristics depending on an optical path. Accordingly, the pattern 500P of the protecting layer 500 may not overlap the light-emitting diode LED. In other words, the through holes formed in the protecting layer 500 may all be spaced (e.g., spaced apart) from the light-emitting diode LED.

As a result, through the above structure, the display panel 10 according to one or more embodiments of the present disclosure may increase the physical coupling force of the upper cover layer 300 while protecting the light-emitting diode LED, thereby improving elongation property and mechanical stability of the display panel 10.

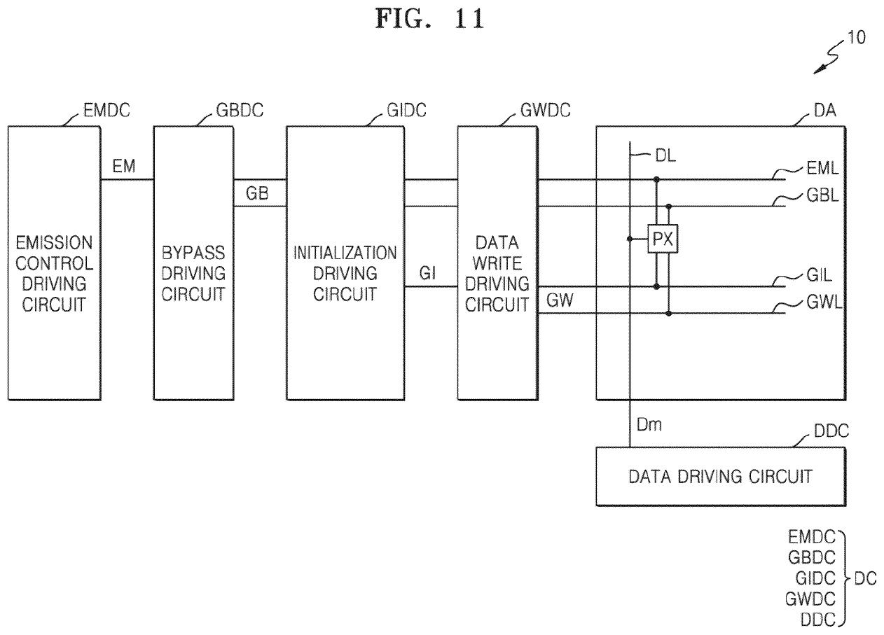

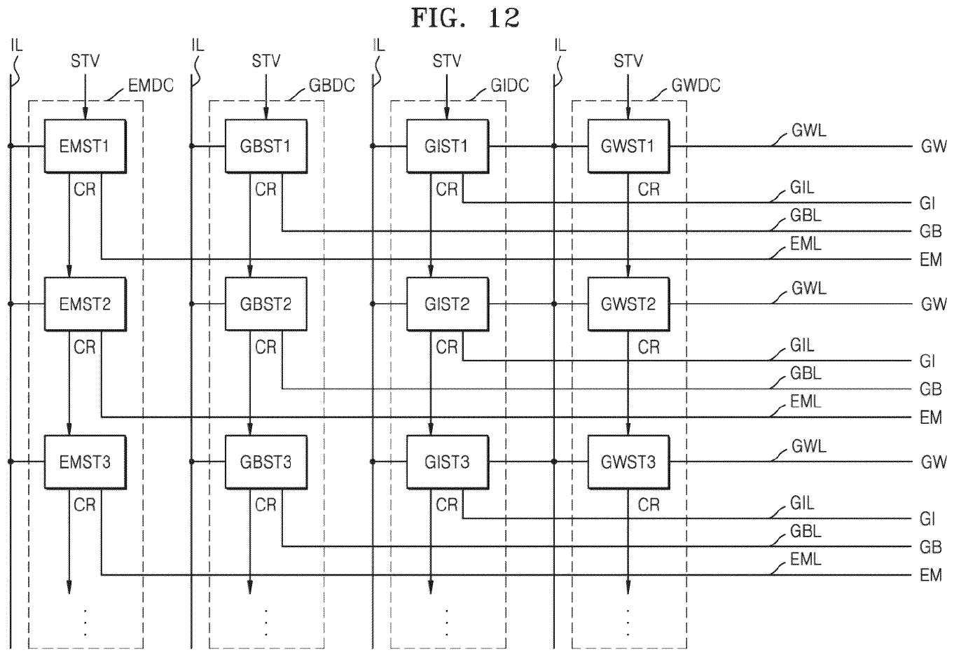

FIG. 11 is a diagram schematically showing a gate driving circuit of a display panel, according to one or more embodiments of the present disclosure. FIG. 12 is a diagram schematically showing a gate driving circuit of a display panel, according to one or more embodiments of the present disclosure.

Referring to FIG. 11, a plurality of pixels PX and signal lines for applying electrical signals to the plurality of pixels PX may be arranged in the display area DA. The signal lines for applying electrical signals to each of the pixels PX may include the plurality of data lines DL, the plurality of emission control lines EML, the plurality of scan signal lines GWL, the plurality of initialization control lines GIL, and the plurality of bypass control lines GBL.

A driving circuit DC configured to supply a signal for driving the pixels PX may be arranged outside the display area DA. The driving circuit DC may include a data driving circuit DDC and the gate driving circuit GDC (FIG. 4), and the gate driving circuit GDC (FIG. 4) may include an emission control driving circuit EMDC, a bypass driving circuit GBDC, an initialization driving circuit GIDC, and a data write driving circuit GWDC. The data driving circuit DDC may be arranged adjacent to a lower side surface of the display area DA to be connected to the data lines DL and output the data signal Dm to the data lines DL.

The emission control driving circuit EMDC (or a first gate driving circuit), the bypass driving circuit GBDC (or a second gate driving circuit), the initialization driving circuit GIDC (or a third gate driving circuit), and the data write driving circuit GWDC (or a fourth gate driving circuit) may be arranged adjacent to a left side surface or a right side surface of the display area DA. The emission control driving circuit EMDC may be connected to the emission control lines EML and output the emission control signal EM to the emission control lines EML. The bypass driving circuit GBDC may be connected to the bypass control lines GBL and output the bypass control signal GB to the bypass control lines GBL. The initialization driving circuit GIDC may be connected to the initialization control lines GIL and output the initialization control signal GI to the initialization control lines GIL. The data write driving circuit GWDC may be connected to the scan signal lines GWL and output the scan signal GW.

Referring to FIG. 12, the emission control driving circuit EMDC may be implemented as a shift register including a plurality of emission control stages EMST1, EMST2, EMST3, and so on. Each of the emission control stages EMST1, EMST2, EMST3, and so on may be a sub-driving circuit. Each of the emission control stages EMST1, EMST2, EMST3, and so on may be connected to the corresponding emission control line EML and output the emission control signal EM to the corresponding emission control line EML. The first emission control stage EMST1 may output the emission control signal EM in response to an external start signal STV and each of the remaining emission control stages EMST2, EMST3, and so on excluding the first emission control stage EMST1 may receive, as a start signal, a carry signal CR output from a previous stage. Each of the emission control stages EMST1, EMST2, EMST3, and so on may be connected to a plurality of input lines IL arranged outside the emission control stages EMST1, EMST2, EMST3, and so on.

The bypass driving circuit GBDC may be implemented as a shift register including a plurality of bypass stages GBST1, GBST2, GBST3, and so on. Each of the bypass stages GBST1, GBST2, GBST3, and so on may be a sub-driving circuit. Each of the bypass stages GBST1, GBST2, GBST3, and so on may be connected to the corresponding bypass control line GBL and output the bypass control signal GB to the corresponding bypass control line GBL. The first bypass stage GBST1 may output the bypass control signal GB in response to the external start signal STV and each of the remaining bypass stages GBST2, GBST3, and so on excluding the first bypass stage GBST1 may receive, as a start signal, the carry signal CR output from a previous stage. Each of the bypass stages GBST1, GBST2, GBST3, and so on may be connected to the plurality of input lines IL arranged outside the bypass stages GBST1, GBST2, GBST3, and so on.

The initialization driving circuit GIDC may be implemented as a shift register including a plurality of initialization stages GIST1, GIST2, GIST3, and so on. Each of the initialization stages GIST1, GIST2, GIST3, and so on may be a sub-driving circuit. Each of the initialization stages GIST1, GIST2, GIST3, and so on may be connected to the initialization control line GIL and output the initialization control signal GI to the corresponding initialization control line GIL. The first initialization stage GIST1 may output the initialization control signal GI in response to the external start signal STV and each of the remaining initialization stages GIST2, GIST3, and so on excluding the first initialization stage GIST1 may receive, as a start signal, the carry signal CR output from a previous stage. Each of the initialization stages GIST1, GIST2, GIST3, and so on may be connected to the plurality of input lines IL arranged outside the initialization stages GIST1, GIST2, GIST3, and so on.

The data write driving circuit GWDC may be implemented as a shift register including a plurality of data write stages GWST1, GWST2, GWST3, and so on. Each of the data write stages GWST1, GWST2, GWST3, and so on may be a sub-driving circuit. Each of the data write stages GWST1, GWST2, GWST3, and so on may be connected to the corresponding scan signal line GWL and output the scan signal GW to the corresponding scan signal line GWL. The first data write stage GWST1 may output the scan signal GW in response to the external start signal STV and each of the remaining data write stages GWST2, GWST3, and so on excluding the first data write stage GWST1 may receive, as a start signal, the carry signal CR output from a previous stage. Each of the data write stages GWST1, GWST2, GWST3, and so on may be connected to the plurality of input lines IL arranged outside the data write stages GWST1, GWST2, GWST3, and so on.

The plurality of input lines IL may include a plurality of voltage lines and signal lines including a plurality of clock wires. In FIG. 12, only one input line is illustrated for convenience of illustration. The plurality of input lines IL may include a gate high voltage wire, a gate low voltage wire, an initiation signal wire, a first clock wire, a second clock wire, a carry wire, and/or a reset signal wire.

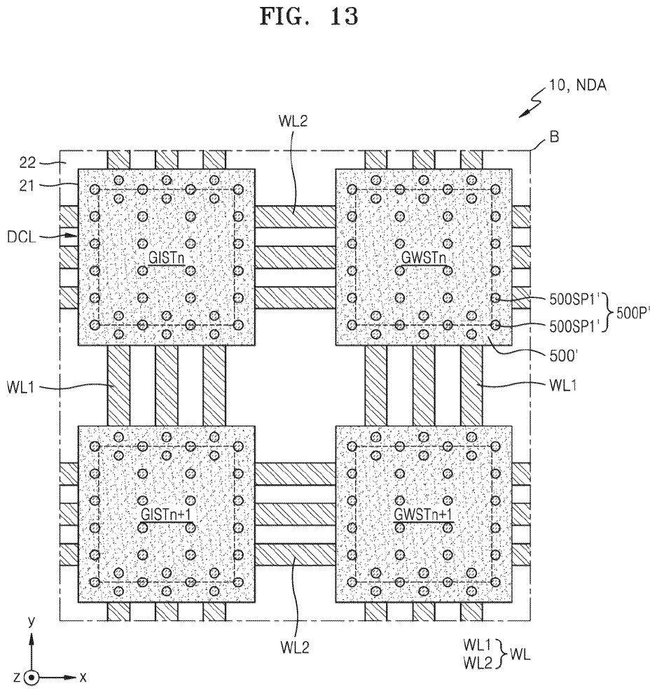

FIG. 13 is a plan view schematically showing a portion of a display panel, according to one or more embodiments of the present disclosure. FIG. 13 is a plan view schematically showing a region B of the display panel 10 of FIG. 4.

Referring to FIG. 13, the non-display area NDA may include a plurality of third areas 21 and a fourth area 22 around (e.g., surrounding) the plurality of third areas 21. The third areas 21 may have a smaller elongation than the fourth area 22. Accordingly, when the display panel 10 is stretched, the third areas 21 may be deformed less than the fourth area 22. As described above, the third areas 21 may be referred to as a low deformation area (or a low deformation portion). The third areas 21 is an area arranged in the non-display area NDA and may correspond to the first area 11 (FIG. 9A) of the display area DA (FIG. 9A). Also, the third area 21 is an area where stages of a driving circuit is arranged and may be referred to as a driving circuit area.

For example, the third area 21 may be an area where a driving circuit layer DCL corresponding to the pixel circuit layer PCL (FIG. 10) of the display area DA (FIG. 9A) is arranged. Like the pixel circuit layer PCL (FIG. 10), the driving circuit layer DCL may include the inorganic insulating stack IIL (FIG. 10), a driving circuit, and the organic insulating layer OIL (FIG. 10).

The fourth area 22 may surround the third area 21 and have a larger elongation than the third area 21. The fourth area 22 may be an area that is mainly deformed according to stretching of a display device. The fourth area 22 is arranged between the plurality of third areas 21 and may be referred to as a connecting portion that connects the third areas 21. Also, the fourth area 22 may be referred to as a main deformation area (or a main deformation portion) or a high deformation area (or a high deformation portion). The fourth area 22 is an area arranged in the non-display area NDA and may be an area corresponding to the second area 12 (FIG. 9A) of the display area DA (FIG. 9A).

The gate driving circuit GDC (FIG. 4) supplying a gate signal to each pixel may be arranged in the third area 21. In detail, the gate driving circuit GDC (FIG. 4) arranged in the non-display area NDA may be arranged such that the emission control driving circuit EMDC (FIG. 11), the bypass driving circuit GBDC (FIG. 11), the initialization driving circuit GIDC (FIG. 11), and the data write driving circuit GWDC (FIG. 11) are arranged in the stated order from the outside towards the display area DA (FIG. 4).

According to one or more embodiments, one driver stage may be arranged in one third area 21. For example, as shown in FIG. 13, an nth initialization stage GISTn may be arranged in one third area 21 and an (n+1)th initialization stage GISTn+1 may be arranged in another third area 21 adjacent to the one third area 21 in a second direction (e.g., the y direction). In a similar manner, an nth data write stage GWSTn may be arranged in one third area 21 and an (n+1)th data write stage GWSTn+1 may be arranged in another third area 21 adjacent to the one third area 21 in the second direction (e.g., the y direction). Also, the third area 21 where the nth initialization stage GISTn is arranged and the third area 21 where the nth data write stage GWSTn is arranged may be adjacent to each other in the first direction (e.g., the x direction). However, the present disclosure is not limited thereto, and according to one or more embodiments, two or more driver stages may be arranged in one third area 21.

According to one or more embodiments, a peripheral protecting layer 500′ may be arranged on the driving circuit layer DCL in the non-display area NDA. The peripheral protecting layer 500′ may be arranged on the third area 21 to protect the driving circuit arranged in the third area 21. The peripheral protecting layer 500′ may be patterned in the third area 21. As one peripheral protecting layer 500′ is patterned in one third area 21, the plurality of peripheral protecting layers 500′ may be arranged in the non-display area NDA. In other words, the plurality of peripheral protecting layers 500′ may be spaced (e.g., spaced apart) from each other with the fourth area 22 therebetween.

Like the protecting layer 500 (FIG. 9B) of the display area DA (FIG. 9B), the peripheral protecting layer 500′ of the non-display area NDA may also include a transparent material having a greater modulus value than the upper cover layer 300 (FIG. 10). According to one or more embodiments, the peripheral protecting layer 500′ of the non-display area NDA may include a same material as the protecting layer 500 (FIG. 9B) of the display area DA (FIG. 9B). For example, the peripheral protecting layer 500′ may include SU-8.

According to one or more embodiments, the peripheral protecting layer 500′ may include a peripheral pattern 500P′ from which a portion of the peripheral protecting layer 500′ is removed. The peripheral pattern 500P′ of the peripheral protecting layer 500′ may have the shape of a through hole penetrating the peripheral protecting layer 500′. When the peripheral pattern 500P′ having the shape of the through hole is formed in the peripheral protecting layer 500′ and the upper cover layer 300 (FIG. 10) is filled in the peripheral pattern 500P′, the physical coupling force between the upper cover layer 300 (FIG. 10) and the lower structure may be increased.

According to one or more embodiments, the peripheral pattern 500P′ of the peripheral protecting layer 500′ may include a plurality of first peripheral sub-patterns 500SP1′ spaced (e.g., spaced apart) from each other in a plan view. The plurality of first peripheral sub-patterns 500SP1′ may each have the shape of a through hole penetrating the peripheral protecting layer 500′. In this regard, as shown in FIG. 13, the plurality of first peripheral sub-patterns 500SP1′ may have the shape of a circle in a plan view. However, the present disclosure is not limited thereto, and the plurality of first peripheral sub-patterns 500SP1′ may have the shape of a polygon or the shape of an oval in a plan view.

According to one or more embodiments, a proportion of the volume occupied by the pattern 500P (FIG. 9B) in the protecting layer 500 (FIG. 9B) of the display area DA (FIG. 9B) may be the same as a proportion of the volume occupied by the peripheral pattern 500P′ in the peripheral protecting layer 500′ of the non-display area NDA. A proportion of the volume occupied by the plurality of through holes in the protecting layer 500 (FIG. 9B) may be the same as a proportion of the volume occupied by the plurality of through holes in the peripheral protecting layer 500′. In other words, a pattern density of the protecting layer 500 (FIG. 9B) and a pattern density of the peripheral protecting layer 500′ may be the same. As a result, not only the plurality of protecting layers 500 arranged in the display area DA all have a uniform pattern density, but also the plurality of protecting layers 500 and the plurality of peripheral protecting layers 500′ arranged in the display panel 10 all have a uniform pattern density.

For example, the volume of one first sub-pattern 500SP1 arranged in the first protecting layer 500-1 (FIG. 9B) may be the same as the volume of one first peripheral sub-pattern 500SP1′ arranged in the peripheral protecting layer 500′, and the number of first sub-patterns 500SP1 arranged in the first protecting layer 500-1 (FIG. 9B) may be the same as the number of first peripheral sub-patterns 500SP1′ arranged in the peripheral protecting layer 500′. However, the present disclosure is not limited thereto, and the peripheral patterns 500P′ of the peripheral protecting layers 500′ may have different shapes and arrangements as long as the volumes of patterns included in the protecting layer 500 (FIG. 9B) and the peripheral protecting layer 500′ are the same.

When the pattern 500P and the peripheral pattern 500P′ are formed such that the plurality of patterns 500P of the protecting layers 500 (FIG. 9B) and the plurality of peripheral patterns 500P′ have a uniform pattern density, respectively, the volume of the upper cover layer 300 (FIG. 10) filled in the through holes of the pattern 500P of the protecting layer 500 (FIG. 9B) and the peripheral pattern 500P′ may also be uniform. Accordingly, the physical coupling force between the upper cover layer 300 (FIG. 10) and the lower structure is uniformly improved not only in the display area DA (FIG. 9B), but also in the non-display area NDA, thereby promoting the mechanical stability of the display panel 10. In addition, the upper cover layer 300 (FIG. 10) includes a material having a relatively lower modulus than the protecting layer 500 (FIG. 9B) and the peripheral protecting layer 500′, and thus, the elongation property of the display panel 10 may also be uniformly improved in the display area DA and the non-display area NDA.

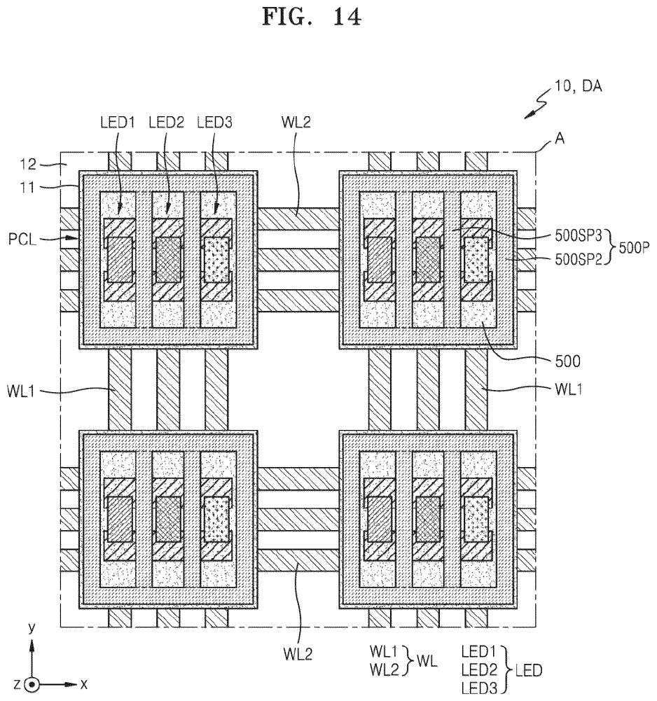

FIG. 14 is a plan view schematically showing a portion of a display panel, according to one or more embodiments of the present disclosure. Referring to FIG. 14, features other than features about the pattern 500P of the protecting layer 500 are the same as those described with reference to FIGS. 9A-10. Among components of FIG. 14, descriptions about same reference numerals are replaced with those described above with reference to FIGS. 9A-10, and differences will be mainly described below.

Referring to FIG. 14, the protecting layer 500 may be arranged on the light-emitting diode LED. The protecting layer 500 may be arranged in the first area 11 and protect the light-emitting elements by covering the first light-emitting diode LED1, the second light-emitting diode LED2, and the third light-emitting diode LED3 arranged in the first area 11.

According to one or more embodiments, the protecting layer 500 may include the pattern 500P from which a portion of the protecting layer 500 is removed. The pattern 500P of the protecting layer 500 may have the shape of a through hole penetrating the protecting layer 500. When the pattern 500P having the shape of the through hole is formed in the protecting layer 500 and the upper cover layer 300 (FIG. 10) is filled in the pattern 500P, the physical coupling force between the upper cover layer 300 (FIG. 10) and a lower structure may be increased.

According to one or more embodiments, the pattern 500P of the protecting layer 500 may be spaced (e.g., spaced apart) from the light-emitting diode LED in a plan view. This is to prevent an optical characteristic from being changed due to a difference in a refractive index when the pattern 500P of the protecting layer 500 is arranged on the light-emitting diode LED as the upper cover layer 300 (FIG. 10) is filled in the pattern 500P of the protecting layer 500. In other words, the pattern 500P of the protecting layer 500 may not overlap the light-emitting diode LED.

In detail, the pattern 500P of the protecting layer 500 may include a second sub-pattern 500SP2 extending along an edge of the first area 11. In other words, the second sub-pattern 500SP2 may have a shape extending in the first direction (e.g., the x direction) and the second direction (e.g., the y direction) along an outer edge of the pixel circuit layer PCL. In other words, the second sub-pattern 500SP2 may be arranged on the pixel circuit layer PCL and have a closed loop shape in a plan view.

In addition, the pattern 500P of the protecting layer 500 may further include a third sub-pattern 500SP3 arranged between the light-emitting diodes LED adjacent to each other. When the first light-emitting diode LED1, the second light-emitting diode LED2, and the third light-emitting diode LED3 are arranged along the first direction (e.g., the x direction), the third sub-pattern 500SP3 may extend in the second direction (e.g., the y direction) in an area between the adjacent light-emitting diodes LED. For example, the third sub-pattern 500SP3 may be arranged between the first light-emitting diode LED1 and the second light-emitting diode LED2, while extending in the second direction (e.g., the y direction). Alternatively, the third sub-pattern 500SP3 may be arranged between the second light-emitting diode LED2 and the third light-emitting diode LED3, while extending in the second direction (e.g., the y direction).

As a result, through the above structure, the display panel 10 according to one or more embodiments of the present disclosure may increase the physical coupling force of the upper cover layer 300 (FIG. 10) while protecting the light-emitting diode LED, thereby improving elongation property and mechanical stability of the display panel 10.

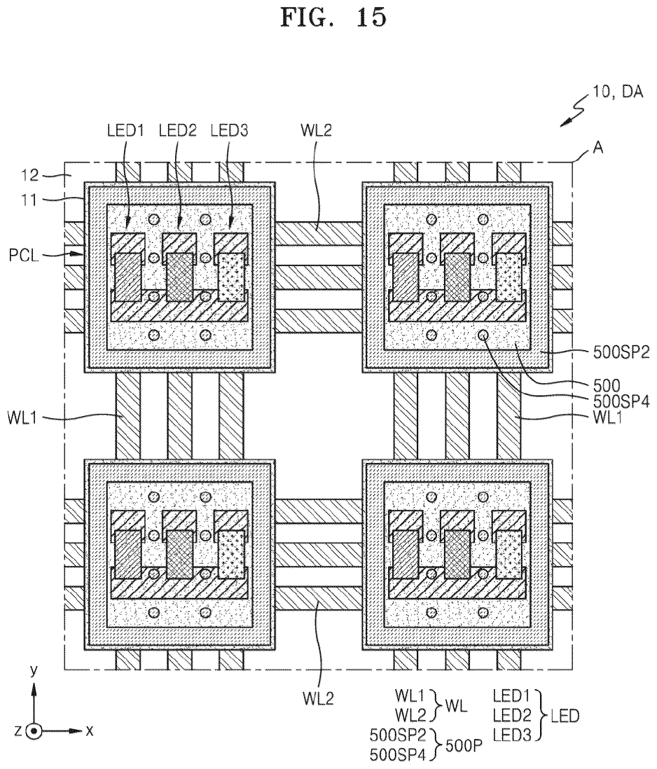

FIG. 15 is a plan view schematically showing a portion of a display panel, according to one or more embodiments of the present disclosure. Referring to FIG. 15, features other than features about the pattern 500P of the protecting layer 500 are the same as those described with reference to FIGS. 9A-10. Among components of FIG. 15, descriptions about same reference numerals are replaced with those described above with reference to FIGS. 9A-10, and differences will be mainly described below.

Referring to FIG. 15, the protecting layer 500 may be arranged on the light-emitting diode LED. The protecting layer 500 may be arranged in the first area 11 and protect the light-emitting elements by covering the first light-emitting diode LED1, the second light-emitting diode LED2, and the third light-emitting diode LED3 arranged in the first area 11.

According to one or more embodiments, the protecting layer 500 may include the pattern 500P from which a portion of the protecting layer 500 is removed. The pattern 500P of the protecting layer 500 may have the shape of a through hole penetrating the protecting layer 500. When the pattern 500P having the shape of the through hole is formed in the protecting layer 500 and the upper cover layer 300 (FIG. 10) is filled in the pattern 500P, the physical coupling force between the upper cover layer 300 (FIG. 10) and the lower structure may be increased.

According to one or more embodiments, the pattern 500P of the protecting layer 500 may be spaced (e.g., spaced apart) from the light-emitting diode LED in a plan view. This is to prevent an optical characteristic from being changed due to a difference in a refractive index when the pattern 500P of the protecting layer 500 is arranged on the light-emitting diode LED as the upper cover layer 300 (FIG. 10) is filled in the pattern 500P of the protecting layer 500. In other words, the pattern 500P of the protecting layer 500 may not overlap the light-emitting diode LED.

In detail, the pattern 500P of the protecting layer 500 may include the second sub-pattern 500SP2 extending along an edge of the first area 11. In other words, the second sub-pattern 500SP2 may have a shape extending in the first direction (e.g., the x direction) and the second direction (e.g., the y direction) along an outer edge of the pixel circuit layer PCL. In other words, the second sub-pattern 500SP2 may be arranged on the pixel circuit layer PCL and have a closed loop shape in a plan view.

In addition, the pattern 500P of the protecting layer 500 may further include a plurality of fourth sub-patterns 500SP4 spaced (e.g., spaced apart) from each other in a plan view and arranged between the light-emitting diodes LED adjacent to each other. The plurality of fourth sub-patterns 500SP4 may each have the shape of a through hole penetrating the protecting layer 500. In this regard, as shown in FIG. 15, the plurality of fourth sub-patterns 500SP4 may have the shape of a circle in a plan view. However, the present disclosure is not limited thereto, and the plurality of fourth sub-patterns 500SP4 may have the shape of a polygon or the shape of an oval in a plan view.

When the first light-emitting diode LED1, the second light-emitting diode LED2, and the third light-emitting diode LED3 are arranged along the first direction (e.g., the x direction), the plurality of fourth sub-patterns 500SP4 may be arranged along the second direction (e.g., the y direction) in an area between the adjacent light-emitting diodes LED. For example, the plurality of fourth sub-patterns 500SP4 may be arranged between the first light-emitting diode LED1 and the second light-emitting diode LED2, while extending in the second direction (e.g., the y direction). Alternatively, the plurality of fourth sub-patterns 500SP4 may be arranged between the second light-emitting diode LED2 and the third light-emitting diode LED3, while extending in the second direction (e.g., the y direction).

As a result, through the above structure, the display panel 10 according to one or more embodiments of the present disclosure may increase the physical coupling force of the upper cover layer 300 (FIG. 10) while protecting the light-emitting diode LED, thereby improving the elongation property and mechanical stability of the display panel 10.

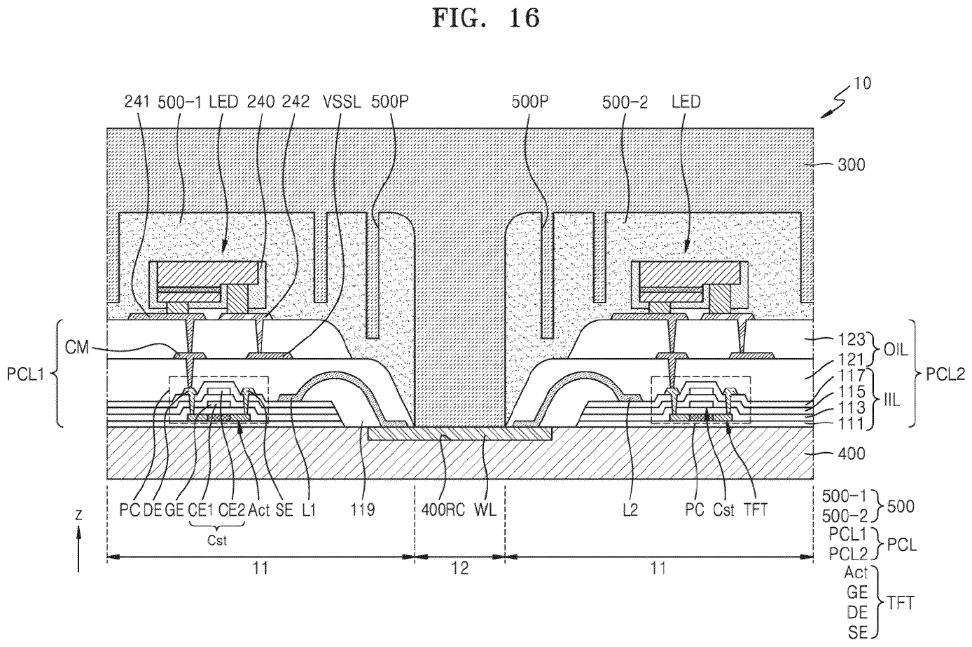

FIG. 16 is a cross-sectional view schematically showing a portion of a display panel, according to one or more embodiments of the present disclosure. Referring to FIG. 16, features other than features about the pattern 500P of the protecting layer 500 are the same as those described with reference to FIGS. 9A-10. Among components of FIG. 16, descriptions about same reference numerals are replaced with those described above with reference to FIGS. 9A-10, and differences will be mainly described below.

Referring to FIG. 16, the protecting layer 500 covering the light-emitting diode LED may be arranged on the pixel circuit layer PCL. For example, the first protecting layer 500-1 covering the light-emitting diode LED on the first pixel circuit layer PCL1 may be arranged on the first pixel circuit layer PCL1, and the second protecting layer 500-2 covering the light-emitting diode LED on the second pixel circuit layer PCL2 may be arranged on the second pixel circuit layer PCL2.

According to one or more embodiments, the protecting layer 500 may include the pattern 500P from which a portion of the protecting layer 500 is removed. As shown in FIG. 16, the pattern 500P of the protecting layer 500 may have a recess shape in which a top surface of the protecting layer 500 is dug. In other words, the pattern 500P of the protecting layer 500 may have a concave shape or a trench shape in which the top surface of the protecting layer 500 is dug. The upper cover layer 300 may be arranged on the protecting layer 500, and thus, the pattern 500P of the protecting layer 500 may be filled with the upper cover layer 300. In other words, the upper cover layer 300 may be arranged in a plurality of recess portions formed in the protecting layer 500.

As described above, even when the upper cover layer 300 is filled in the pattern 500P by forming the pattern 500P having the recess shape in the protecting layer 500, the physical coupling force between the upper cover layer 300 and the lower structure may be increased and the mechanical stability of the display panel 10 may be improved. Also, as described above, even when the pattern 500P of the protecting layer 500 has the recess shape, the pattern 500P of the protecting layer 500 may not overlap the light-emitting diode LED. In other words, the plurality of recess portions formed in the protecting layer 500 may all be spaced (e.g., spaced apart) from the light-emitting diode LED. This is to prevent an optical characteristic from being changed according to an optical path of light emitted from the light-emitting diode LED due to different refractive indexes between the protecting layer 500 and the upper cover layer 300.

As a result, through the above structure, the display panel 10 according to one or more embodiments of the present disclosure may increase the physical coupling force of the upper cover layer 300 while protecting the light-emitting diode LED, thereby improving the elongation property and mechanical stability of the display panel 10.

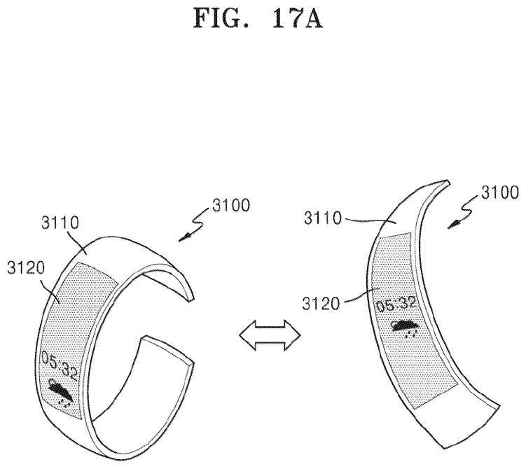

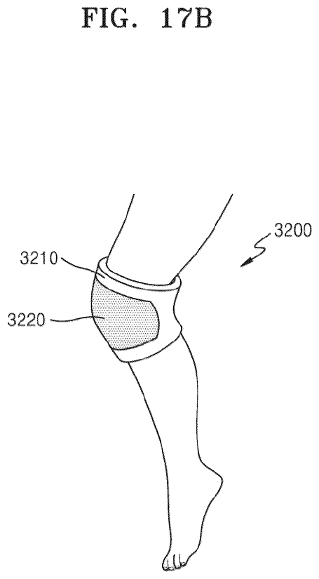

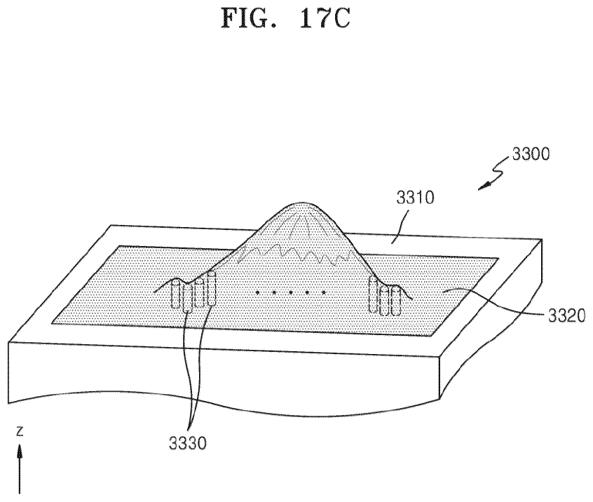

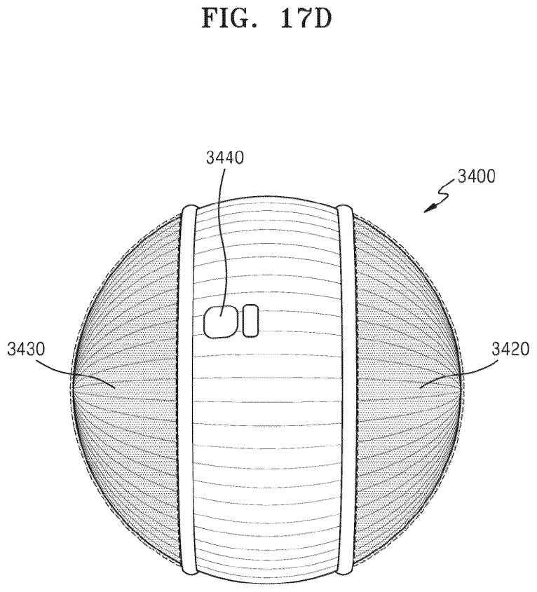

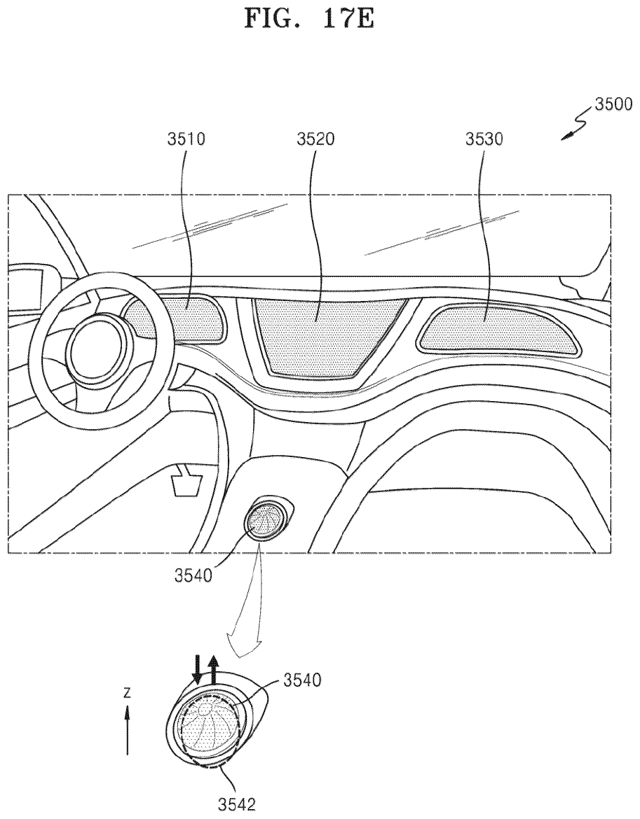

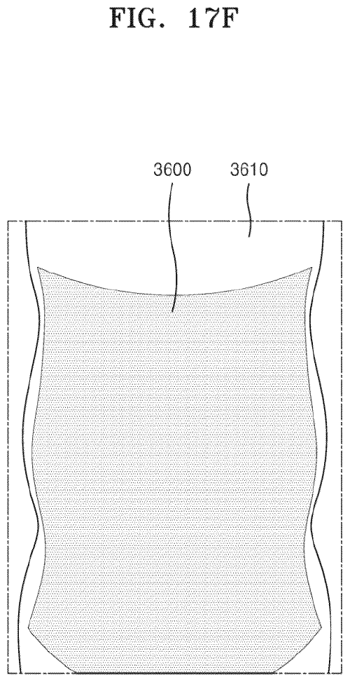

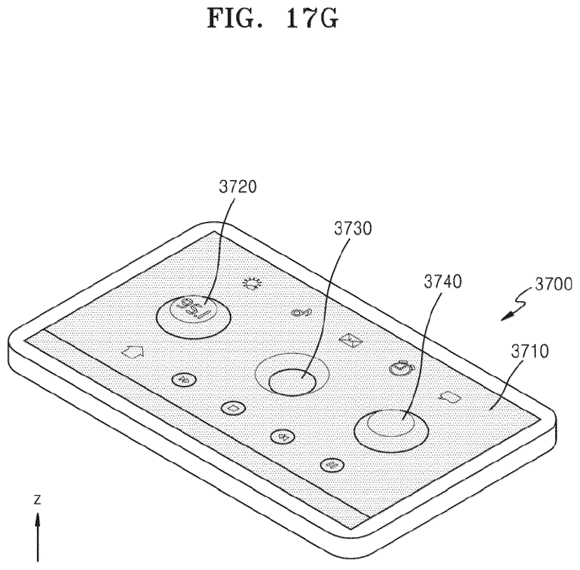

FIGS. 17A-17G are each a perspective view of an example of an electronic device including a display panel, according to one or more embodiments of the present disclosure.

Referring to FIG. 17A, a display panel according to one or more embodiments of the present disclosure may be used for a wearable electronic device 3100 that may be worn on a part of the body of a user. The wearable electronic device 3100 may include a body portion 3110 and a display portion 3120 provided in the body portion 3110. The display panel according to one or more embodiments of the present disclosure may be used as a display portion 3120 of the wearable electronic device 3100. The wearable electronic device 3100 of FIG. 17A may be transformed. According to one or more embodiments, the wearable electronic device 3100 may be used as a smart watch or a smart phone according to the user's choice.

FIG. 17B illustrates a medical electronic device 3200. According to one or more embodiments, the medical electronic device 3200 may include a body portion 3210 and a light-emitting portion 3220. The display panel according to one or more embodiments of the present disclosure may be used as the light-emitting portion 3220 of the medical electronic device 3200. The light-emitting portion 3220 may emit, to the body of a patient, light of a uniform wavelength band (e.g., infrared light, visible light, and/or the like). According to one or more embodiments, the body portion 3210 may include an elastic fiber material and have a structure capable of being worn on the body of a user.

FIG. 17C illustrates an educational electronic device 3300. According to one or more embodiments, the educational electronic device 3300 may include a display portion 3320 provided in a frame 3310. The display portion 3320 may use a display panel according to one or more embodiments of the present disclosure. An image of the sea with waves, a mountain covered with snow, or a volcano with lava may be provided through the display portion 3320, and at this time, the display portion 3320 may be stretched in a height direction (e.g., the z direction) by reflecting the height of waves, mountain, and/or volcano. According to one or more embodiments, a portion of the display portion 3320 may 3-dimensionally display movement of the lava as a height thereof sequentially changes in a direction the lava flows. The educational electronic device 3300 may include a plurality pins 3330 (or stroke portions) arranged on a rear surface of the display portion 3320 such that the display portion 3320 is stretched in the height direction. An image displayed on the display portion 3320 may be 3-dimensionally realized to have heights as the pins 3330 move in the third direction (e.g., the z direction or the −z direction). FIG. 17C shows the educational electronic device 3300, but the purpose thereof is not limited as long as information about a certain image is provided.

Electronic devices shown in FIGS. 17A-17C have variable shapes, but the present disclosure is not limited thereto. As will be described in following embodiments, a display panel according to one or more embodiments of the present disclosure may be used for an electronic device in which a portion representing an image (e.g., a screen) is fixed.

FIG. 17D illustrates a robot 3400 as an electronic device according to one or more embodiments of the present disclosure. The robot 3400 may recognize movement or an object by using a camera portion 3440 and display a specific image to a user through display portions 3420 and 3430. According to one or more embodiments, the display panels may be stretched in various directions as described above, and thus may be assembled to a body frame having a hemispherical shape, and accordingly, the robot 3400 may include hemispherical display portions 3420 and 3430.

FIG. 17E illustrates a vehicle display device 3500 as an electronic device according to one or more embodiments of the present disclosure. The vehicle display device 3500 may include a cluster 3510, a center information display (CID) 3520, and/or a passenger display 3530. A display panel according to one or more embodiments of the present disclosure is stretchable in various directions, and thus may be used for the cluster 3510, the CID 3520, and/or the passenger display 3530 without being restricted by a shape of an internal frame of a vehicle.

FIG. 17E illustrates that the cluster 3510, the CID 3520, and/or the passenger display 3530 are separated from each other, but the present disclosure is not limited thereto. According to one or more embodiments, two or more of the cluster 3510, the CID 3520, and the passenger display 3530 may be integrated with each other.

According to one or more embodiments, the vehicle display device 3500 may include a button 3540 for representing a specific image. Referring to an enlarged view of FIG. 17E, the hemispherical button 3540 may include an object 3542 providing a feeling of using a button while moving in the z direction or the-z direction, and a display device arranged on the object 3542. According to one or more embodiments, when the object 3542 has a 3-dimensionally rounded surface, the display panel may also have the 3-dimensionally rounded surface.

FIG. 17F illustrates an electronic device according to one or more embodiments of the present disclosure being an advertising or exhibitory electronic device 3600. According to one or more embodiments, the advertising or exhibitory electronic device 3600 may be installed at a fixed structure 3610, such as a wall or a pillar. When the structure 3610 includes an uneven surface as shown in FIG. 17F, the advertising or exhibitory electronic device 3600 may also be arranged along the uneven surface of the structure 3610. According to one or more embodiments, the advertising or exhibitory electronic device 3600 may be installed at the structure 3610 by using a thermal contraction film and/or the like.

FIG. 17G illustrates a controller 3700 as an electronic device according to one or more embodiments of the present disclosure. The controller 3700 may include an image type button. For example, the controller 3700 may include first to third button areas 3720 to 3740 provided as a partial area of a display portion 3710 protrudes in the z direction or protrudes in the −z direction (or sunken in the z direction). According to s one or more embodiments, the first and third button areas 3720 and 3740 may protrude in the z direction, and the second button 3730 may protrude in the −z direction (or sunken in the z direction).

Hereinabove, the present disclosure has been described with reference to the embodiments shown in the drawings, but the embodiments are only examples, and it would be understood by one of ordinary skill in the art that various modifications and equivalent embodiments are possible. Accordingly, the true technical protection scope of the present disclosure will be defined by the technical ideas of the appended claims and their equivalents.

### DESCRIPTION OF SYMBOLS

1: Electronic Device
10: Display Panel
DA: Display Area
NDA: Non-Display Area
PC: Pixel Circuit
LED: Light-Emitting Diode
11: First Area
12: Second Area
WL: Connecting Wire
400: Base Layer
PCL: Pixel Circuit Layer
DCL: Driving Circuit Layer
300: Upper Cover Layer
500: Protecting Layer
500′: Peripheral Protecting Layer
500P: Pattern
500P′: Peripheral Pattern

What is claimed is:

1. A display panel comprising:
a base layer including a display area and a non-display area around the display area;
a first pixel circuit layer in the display area of the base layer and comprising a transistor and insulating layers;
at least one first light-emitting diode on the first pixel circuit layer and electrically connected to the transistor of the first pixel circuit layer; and
a first protecting layer on the first pixel circuit layer and covering the at least one first light-emitting diode,
wherein the first protecting layer comprises a first pattern from which a portion of the first protecting layer is removed, and
wherein the first pattern is spaced from the at least one first light-emitting diode in a plan view.

2. The display panel of claim 1, further comprising:
a second pixel circuit layer in the display area of the base layer, the second pixel circuit layer comprising a transistor and insulating layers, the second pixel circuit layer being spaced from the first pixel circuit layer;
at least one second light-emitting diode on the second pixel circuit layer and electrically connected to the transistor of the second pixel circuit layer;
a second protecting layer on the second pixel circuit layer and covering the at least one second light-emitting diode; and
a connecting wire electrically connecting the transistor of the first pixel circuit layer to the transistor of the second pixel circuit layer,
wherein the first protecting layer and the second protecting layer are spaced from each other.

3. The display panel of claim 2, wherein:
the second protecting layer comprises a second pattern from which a portion of the second protecting layer is removed; and
a proportion of volume occupied by the first pattern in the first protecting layer is the same as a proportion of volume occupied by the second pattern in the second protecting layer.

4. The display panel of claim 1, wherein the first pattern has a shape of a through hole penetrating the first protecting layer in a thickness direction of the base layer.

5. The display panel of claim 1, wherein the first pattern has a recess shape in which a top surface of the first protecting layer is dug in a thickness direction of the base layer.

6. The display panel of claim 1, further comprising an upper cover layer on the first protecting layer,
wherein an inside of the first pattern is filled with the upper cover layer.

7. The display panel of claim 6, wherein a modulus value of the first protecting layer is greater than a modulus value of the upper cover layer.

8. The display panel of claim 7, wherein the first protecting layer comprises SU-8.

9. The display panel of claim 1, wherein the first pattern comprises a plurality of first sub-patterns spaced from each other in a plan view.

10. The display panel of claim 9, wherein the plurality of first sub-patterns is arranged outside the first pixel circuit layer in a plan view, or are each arranged in an area between adjacent light-emitting diodes from among the at least one first light-emitting diode.

11. The display panel of claim 1, wherein the first pattern comprises a second sub-pattern extending along an edge of the first pixel circuit layer in a plan view.

12. The display panel of claim 11, wherein:
the at least one first light-emitting diode comprises a first-first light-emitting diode and a first-second light-emitting diode, which are arranged along a first direction; and
the first pattern further comprises a third sub-pattern arranged in an area between the first-first light-emitting diode and the first-second light-emitting diode in a plan view and extending in a second direction intersecting the first direction.

13. The display panel of claim 12, wherein the second sub-pattern and the third sub-pattern are integrated with each other.

14. The display panel of claim 11, wherein:
the at least one first light-emitting diode comprises a first-first light-emitting diode and a first-second light-emitting diode, which are arranged along a first direction; and
the first pattern further comprises a plurality of fourth sub-patterns arranged in an area between the first-first light-emitting diode and the first-second light-emitting diode and spaced from each other in a plan view.

15. The display panel of claim 14, wherein the second sub-pattern and the plurality of fourth sub-patterns are spaced from each other in a plan view.

16. The display panel of claim 1, further comprising:
a driving circuit layer in the non-display area of the base layer and comprising a transistor and insulating layers; and
a peripheral protecting layer on the driving circuit layer,
wherein the peripheral protecting layer comprises a peripheral pattern from which a portion of the peripheral protecting layer is removed.

17. The display panel of claim 16, wherein a proportion of volume occupied by the first pattern in the first protecting layer is the same as a proportion of volume occupied by the peripheral pattern in the peripheral protecting layer.

18. A display panel comprising:
a base layer including a display area and a non-display area around the display area;
a first pixel circuit layer in the display area of the base layer and comprising a transistor and insulating layers;
at least one first light-emitting diode on the first pixel circuit layer and electrically connected to the transistor of the first pixel circuit layer; and
a first protecting layer on the first pixel circuit layer and covering the at least one first light-emitting diode,
wherein a plurality of through holes penetrating the first protecting layer is in the first protecting layer, and
wherein the plurality of through holes is spaced from the at least one first light-emitting diode in a plan view.

19. The display panel of claim 18, further comprising:
a second pixel circuit layer in the display area of the base layer, the second pixel circuit layer comprising a transistor and insulating layers, the second pixel circuit layer being spaced from the first pixel circuit layer;
at least one second light-emitting diode on the second pixel circuit layer and electrically connected to the transistor of the second pixel circuit layer;
a second protecting layer on the second pixel circuit layer and covering the at least one second light-emitting diode; and
a connecting wire electrically connecting the transistor of the first pixel circuit layer to the transistor of the second pixel circuit layer,
wherein the plurality of through holes penetrating the second protecting layer is in the second protecting layer, and
wherein a proportion of volume occupied by the plurality of through holes in the first protecting layer is the same as a proportion of volume occupied by the plurality of through holes in the second protecting layer.

20. An electronic device comprising:
a display panel; and
a lower cover forming an exterior and including an opening exposing a portion of the display panel on a front surface of the electronic device,
wherein the display panel comprises:
a base layer including a display area and a non-display area around the display area;
a first pixel circuit layer in the display area of the base layer and comprising a transistor and insulating layers;
at least one light-emitting diode on the first pixel circuit layer and electrically connected to the transistor of the first pixel circuit layer; and
a first protecting layer on the first pixel circuit layer and covering the at least one light-emitting diode,
wherein the first protecting layer comprises a first pattern from which a portion of the first protecting layer is removed, and
wherein the first pattern is spaced from the at least one light-emitting diode in a plan view.
